(19) United States
(12) Patent Application Publication
(10) Pub. No.: US 2022/0384297 A1
(43) Pub. Date: Dec. 1, 2022

(54) SEMICONDUCTOR DEVICE

(71) Applicant: ROHM CO., LTD., Kyoto-shi, Kyoto (JP)

(72) Inventor: Takumi KANDA, Kyoto-shi (JP)

(21) Appl. No.: 17/755,842

(22) PCT Filed: Dec. 24, 2020
(86) PCT No.: PCT/JP2020/048436

§ 371 Date: May 10, 2022

(30) Foreign Application Priority Data
Jan. 21, 2020 (JP) 2020-007272

(51) Int. Cl. H01L 23/367; H01L 25/07; H01L 23/31; H01L 23/498; H01L 23/00; H01L 23/15

(52) U.S. Cl. CPC H01L 23/367; H01L 25/072; H01L 23/3121; H01L 23/49844; H01L 24/32; H01L 24/48; H01L 24/73; H01L 23/15; H01L 2224/32245; H01L 2224/29139; H01L 24/29; H01L 2224/48245; H01L 2224/73265; H01L 2224/45144; H01L 2224/45147; H01L 2224/45124; H01L 24/45

(57) ABSTRACT

A semiconductor device includes a first insulation member, a first drive conductive layer, a first semiconductor element, a second insulation member, a second drive conductive layer, a second semiconductor element, a connection member, and an encapsulation resin. The encapsulation resin encapsulates the first semiconductor element, the second semiconductor element, and the connection member. The connection member has a higher thermal conductivity than the encapsulation resin. The connection member forms a heat conduction path between the first insulation member and/or the first drive conductive layer and the second insulation member and/or the second drive conductive layer. The connection member has a higher thermal conductivity than the encapsulation resin.

### TECHNICAL FIELD

The present disclosure relates to a semiconductor device.

### BACKGROUND ART

An example of a semiconductor device has a dual surface heat dissipation structure. The semiconductor device includes a first semiconductor element disposed on a first insulation member, a second insulation member located above the first semiconductor element, and a second semiconductor element disposed on the second insulation member (for example, refer to Patent Document 1). In the semiconductor device, a first cooler is attached to the first insulation member, and a second cooler is attached to the second insulation member.

### PRIOR ART DOCUMENT

### Patent Document

Patent Document 1: Japanese Laid-Open Patent Publication No. 2010-97967

### SUMMARY OF THE INVENTION

### Problems that the Invention is to Solve

When the semiconductor device is used, one of the first cooler and the second cooler, for example the second cooler, may be omitted depending on the state of a mount location. In this case, the thermal resistance from the first semiconductor element to the first cooler greatly differs from the thermal resistance from the second semiconductor element to the first cooler. As a result, when the semiconductor device is driven, the temperature increases in one of the first semiconductor element and the semiconductor element having the higher thermal resistance. This may result in a poor performance of the semiconductor device.

It is an objective of the present disclosure to provide a semiconductor device that limits increases in the difference between the thermal resistance from a first semiconductor element to a cooler and the thermal resistance from a second semiconductor element to the cooler.

### Means for Solving the Problems

To achieve the objective described above, a semiconductor device includes a first insulation member including a first insulation main surface and a first insulation rear surface that face opposite sides in a thickness-wise direction, the first insulation rear surface being exposed, a first drive conductive layer disposed on the first insulation main surface, a first semiconductor element mounted on the first drive conductive layer, a second insulation member including a second insulation main surface and a second insulation rear surface that face opposite side in the thickness-wise direction, the second insulation rear surface being exposed, the second insulation member being spaced apart from the first insulation member so that the second insulation main surface is opposed to the first insulation main surface in the thickness-wise direction, a second drive conductive layer disposed on the second insulation main surface, a second semiconductor element mounted on the second drive conductive layer, a connection member forming a heat conduction path between at least one of the first insulation member and the first drive conductive layer and at least one of the second insulation member and the second drive conductive layer; and an encapsulation resin encapsulating the first semiconductor element, the second semiconductor element, and the connection member. The connection member has a higher thermal conductivity than the encapsulation resin.

In this structure, the heat conduction path is formed from the second semiconductor element to a cooler through the connection member. Thus, the difference between the thermal resistance from the first semiconductor element to the cooler and the thermal resistance from the second semiconductor element to the cooler are limited when a cooler is not attached to the second insulation member on which the second semiconductor element is mounted.

### Advantages of the Invention

The semiconductor device described above limits increases in the difference between the thermal resistance from the first semiconductor element to the cooler and the thermal resistance from the second semiconductor element to the cooler.

### BRIEF DESCRIPTION OF THE DRAWINGS

FIG. 1 a perspective view showing an embodiment of a semiconductor device.

FIG. 2 is a plan view of the semiconductor device shown in FIG. 1.

FIG. 3 is a side view of the semiconductor device shown in FIG. 1.

FIG. 4 is a side view of the semiconductor device shown in FIG. 1 as viewed in a direction different from that of FIG. 3.

FIG. 5 is a side view of the semiconductor device shown in FIG. 1 as viewed in a direction different from those of FIGS. 3 and 4.

FIG. 6 is a plan view of a first semiconductor unit of the semiconductor device of the embodiment.

FIG. 7 is a plan view of a second semiconductor unit of the semiconductor device of the embodiment.

FIG. 8 is a cross-sectional view taken along line 8-8 in FIG. 2.

FIG. 9 is a circuit diagram of the semiconductor device of the embodiment.

FIG. 10 is a cross-sectional view showing a comparative example of a semiconductor device.

FIG. 11 is a cross-sectional view showing a modified example of a semiconductor device.

FIG. 12 is a plan view showing a modified example of a second semiconductor unit of a semiconductor device.

FIG. 13 is a plan view showing a modified example of a second semiconductor unit of a semiconductor device.

FIG. 14 is a plan view showing a modified example of a second semiconductor unit of a semiconductor device.

FIG. 15 is a plan view showing a modified example of a second semiconductor unit of a semiconductor device.

FIG. 16 is a plan view showing a modified example of a second semiconductor unit of a semiconductor device.

FIG. 17 is a plan view showing a modified example of a second semiconductor unit of a semiconductor device.

FIG. 18 is a cross-sectional view showing a modified example of a semiconductor device.

FIG. 19 is a cross-sectional view showing a modified example of a semiconductor device.

FIG. 20 is a cross-sectional view showing a modified example of a semiconductor device.

FIG. 21 is a cross-sectional view showing a modified example of a semiconductor device.

FIG. 22 is a plan view showing a modified example of a first semiconductor unit of a semiconductor device.

FIG. 23 is a cross-sectional view showing a modified example of a semiconductor device.

FIG. 24 is a plan view showing a modified example of a second semiconductor unit of a semiconductor device.

### MODES FOR CARRYING OUT THE INVENTION

An embodiment of a semiconductor device will be described below with reference to the drawings. The embodiment described below exemplifies configurations and methods for embodying a technical concept and is not intended to limit the material, shape, structure, layout, dimensions, and the like of each component to those described below. The embodiment described below may undergo various modifications. Components in the drawings may be enlarged for simplicity and clarity. The dimensional proportion of a component may not be drawn to scale or may differ between drawings. In the cross-sectional views, hatching of components may be partially omitted to facilitate understanding.

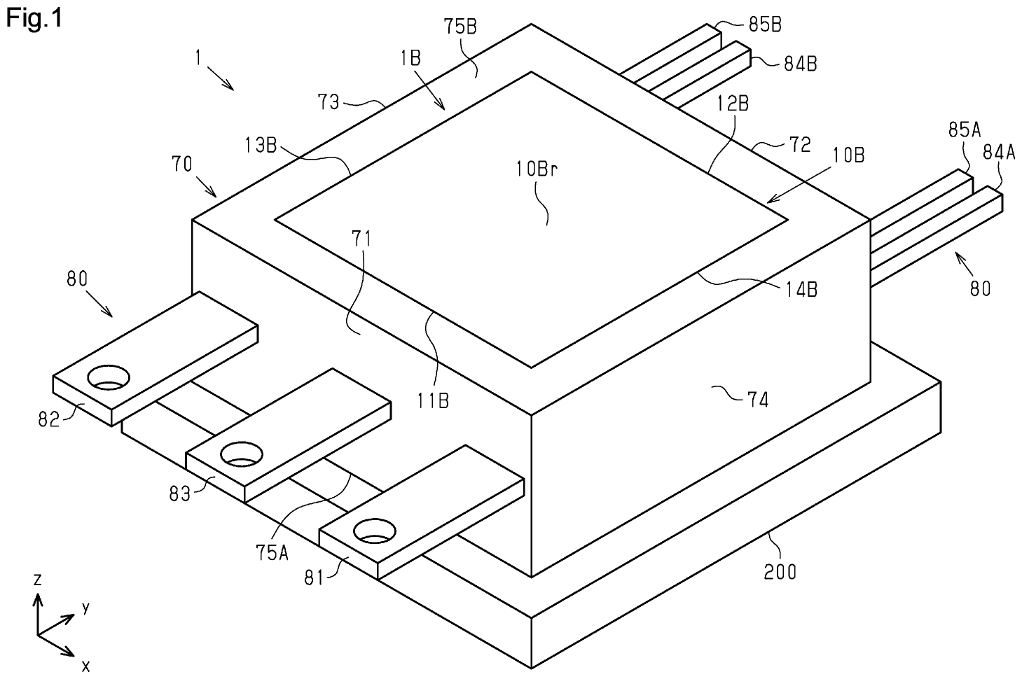

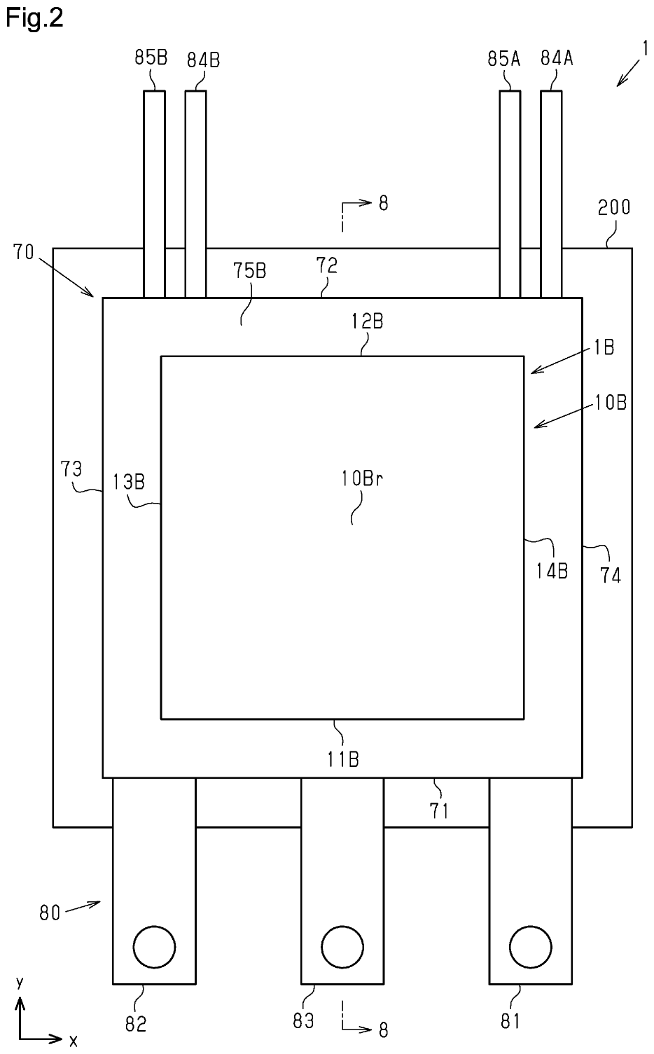

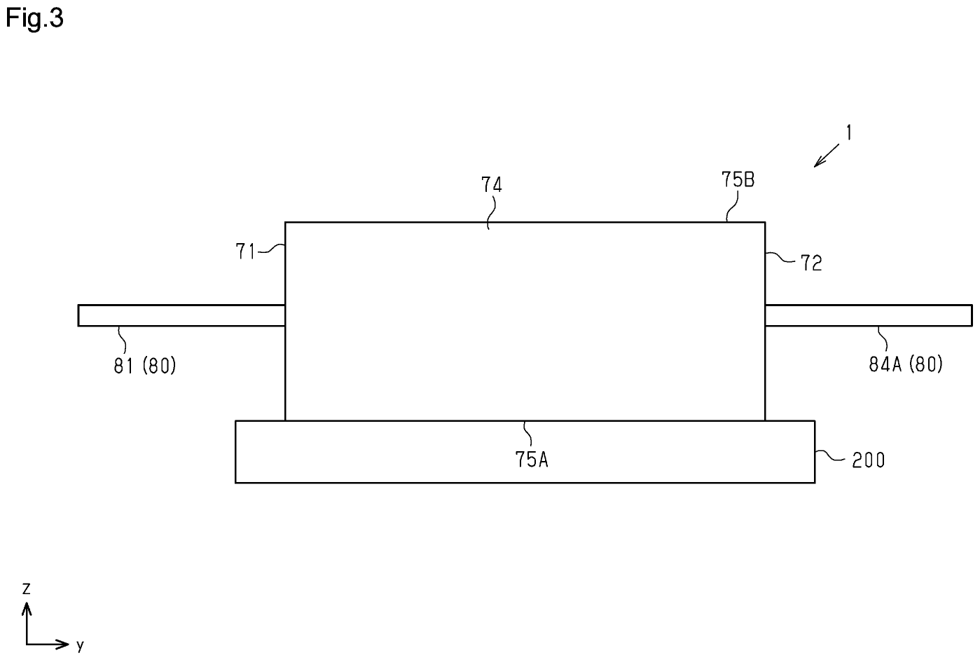

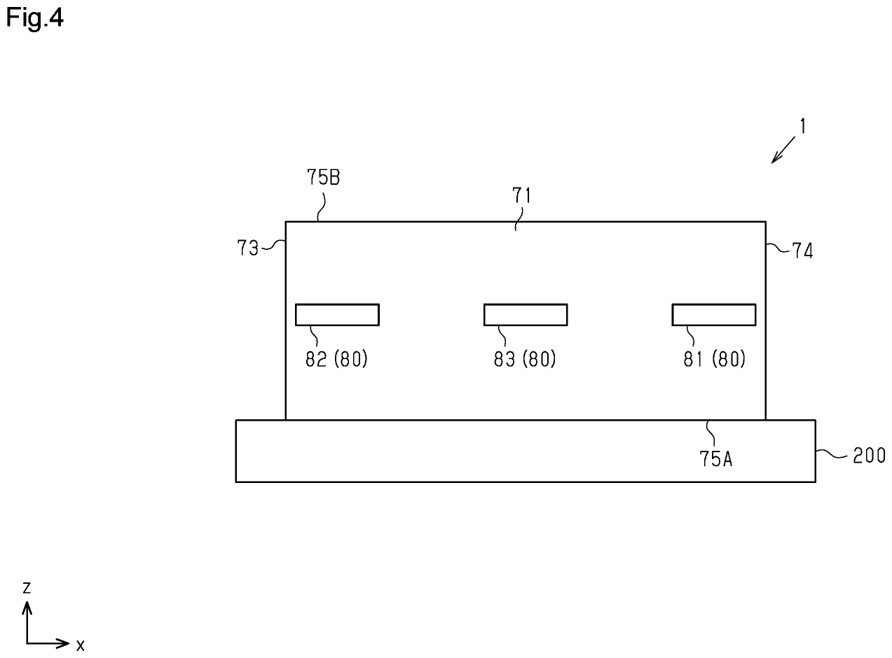

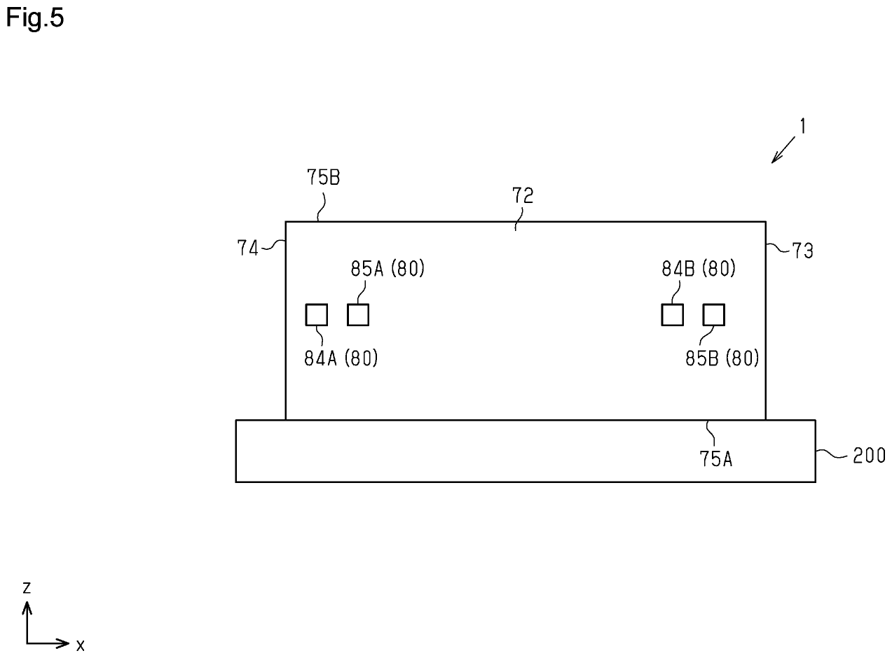

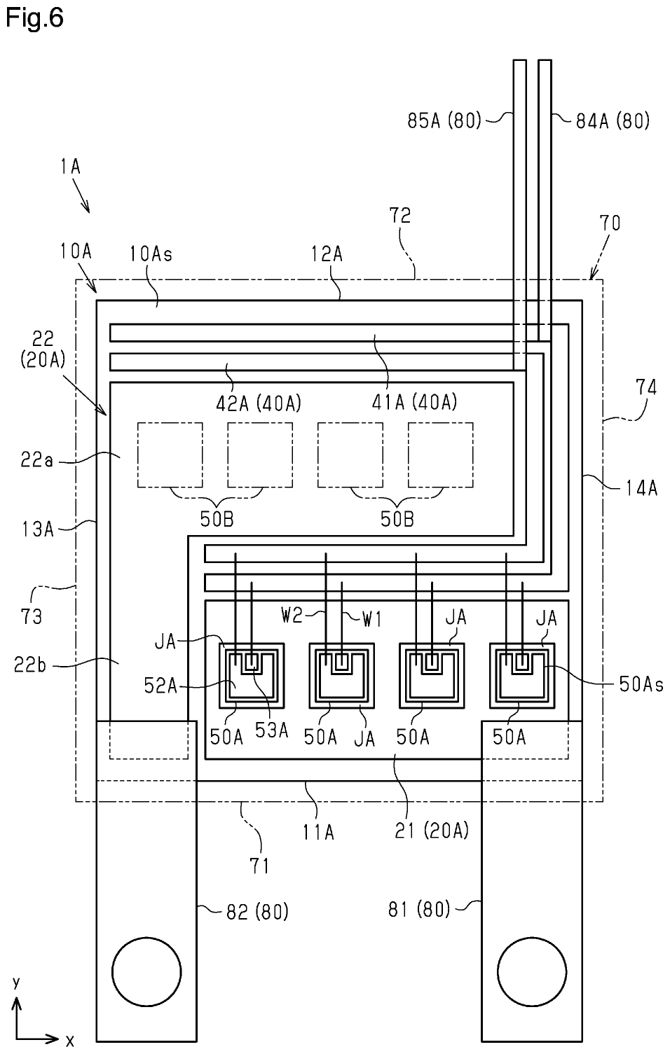

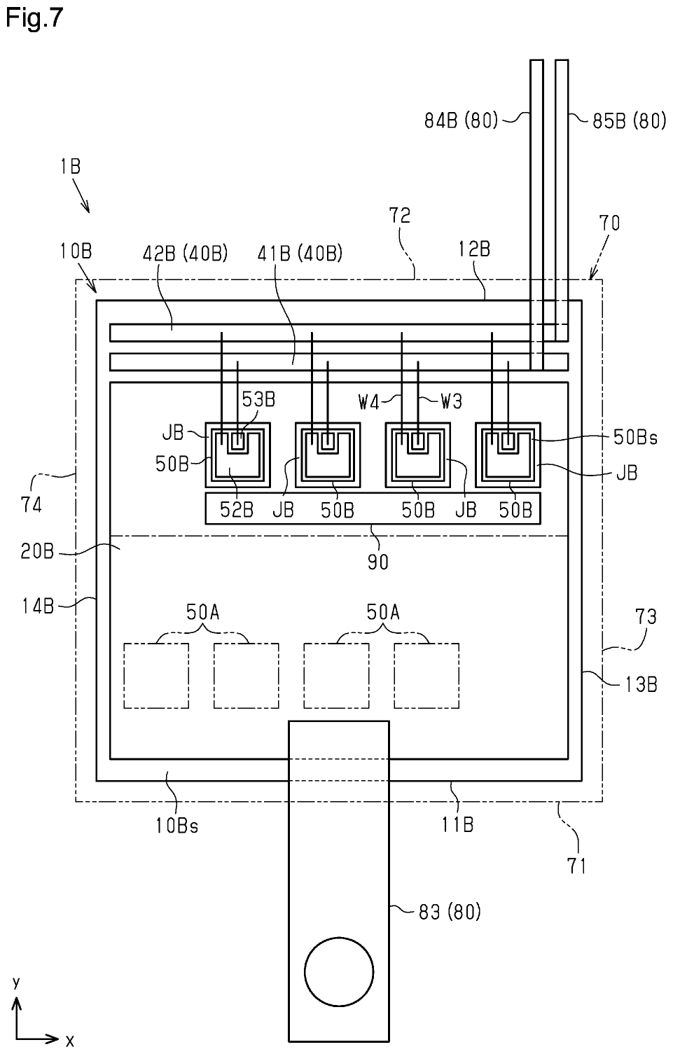

The present embodiment of a semiconductor device 1 will now be described with reference to FIGS. 1 to 9. For the sake of convenience, a cooler 200, which will be described later, is not shown in FIG. 6. Also, an encapsulation resin 70, which will be described later, is not shown in FIGS. 6 and 7.

In the description hereafter, in a plan view of the semiconductor device 1, two directions that are orthogonal to each other are referred to as x-direction and y-direction. The direction orthogonal to the x-direction and the y-direction is referred to as z-direction. The z-direction is an example of a thickness-wise direction. The y-direction is an example of a first direction. The x-direction is an example of a second direction.

As shown in FIGS. 1 to 8, in the semiconductor device 1, the encapsulation resin 70 encapsulates multiple (four, in the present embodiment) first semiconductor elements 50A and multiple (four, in the present embodiment) second semiconductor elements 50B. As shown in FIGS. 1 to 5, when the semiconductor device 1 is attached to the cooler 200, heat transfers to the cooler 200 from the first semiconductor elements 50A (refer to FIG. 6) and the second semiconductor elements 50B (refer to FIG. 7).

The encapsulation resin 70 is formed from an electrically-insulative resin material and is formed from, for example, a black epoxy resin. The encapsulation resin 70 is rectangular-box-shaped and includes resin side surfaces 71 to 74, a first resin main surface 75A, and a second resin main surface 75B.

The resin side surface 71 and the resin side surface 72 face opposite sides in the y-direction. As viewed in the z-direction, the resin side surfaces 71 and 72 extend in the x-direction. The resin side surface 73 and the resin side surface 74 face opposite sides in the x-direction. As viewed in the z-direction, the resin side surfaces 73 and 74 extend in the y-direction. The first resin main surface 75A and the second resin main surface 75B face opposite sides in the z-direction. In the present embodiment, the cooler 200 is attached to the first resin main surface 75A. Therefore, the second resin main surface 75B is located at a side opposite from the cooler 200 in the z-direction.

As shown in FIGS. 1 to 5, the semiconductor device 1 includes terminals 80 projecting from the encapsulation resin 70. The terminals 80 are formed of a metal plate and are formed from, for example, copper (Cu). The terminals 80 includes a first input terminal 81, a second input terminal 82, an output terminal 83, a first control terminal 84A, a first detection terminal 85A, a second control terminal 84B, and a second detection terminal 85B. The first input terminal 81, the second input terminal 82, and the output terminal 83 project from the resin side surface 71 in the y-direction. The first control terminal 84A, the first detection terminal 85A, the second control terminal 84B, and the second detection terminal 85B project from the resin side surface 72 in the y-direction. In other words, the first input terminal 81, the second input terminal 82, and the output terminal 83 project from one side of the encapsulation resin 70, and the first control terminal 84A, the first detection terminal 85A, the second control terminal 84B, and the second detection terminal 85B project from the opposite side of the encapsulation resin 70 in the y-direction.

The first input terminal 81, the second input terminal 82, and the output terminal 83 are arranged at the same position in the z-direction and spaced apart from each other in the x-direction. Each of the terminals 81 to 83 is flat and has a thickness-wise direction conforming to the z-direction.

The first control terminal 84A, the first detection terminal 85A, the second control terminal 84B, and the second detection terminal 85B are arranged at the same position in the z-direction and spaced apart from each other in the x-direction. The first control terminal 84A and the first detection terminal 85A are located toward the resin side surface 74 as viewed in the z-direction. The second control terminal 84B and the second detection terminal 85B are located toward the resin side surface 73 as viewed in the z-direction. Each of the terminals 84A, 84B, 85A, and 85B is tetragonal-rod-shaped and extends in the y-direction.

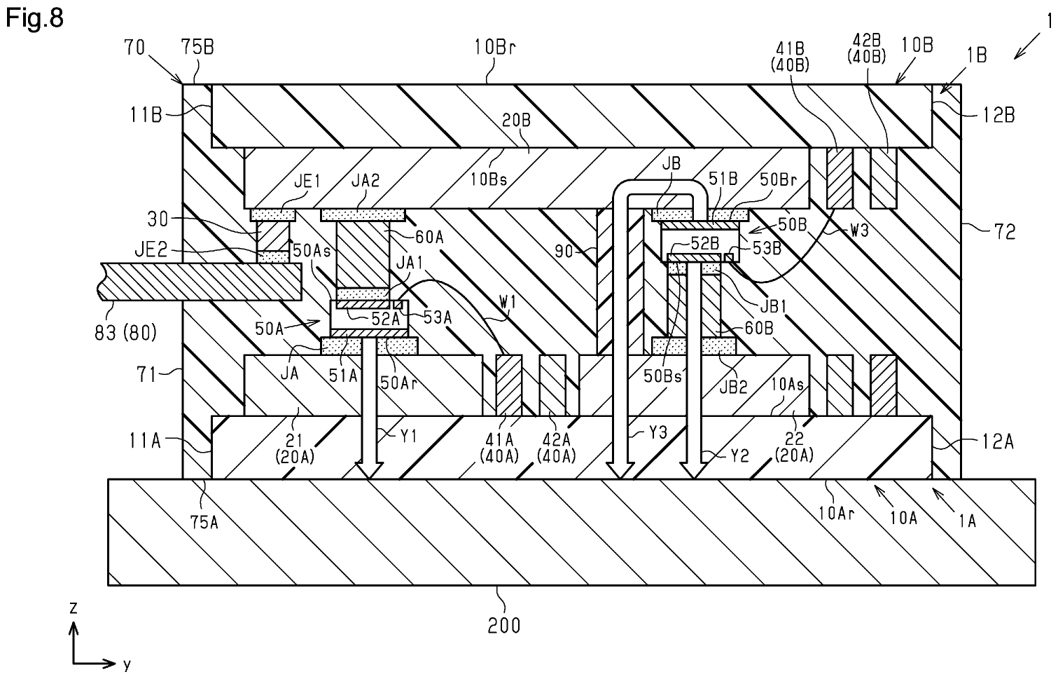

As shown in FIG. 8, the semiconductor device 1 includes a first semiconductor unit 1A and a second semiconductor unit 1B. In the semiconductor device 1, the first semiconductor unit 1A and the second semiconductor unit 1B are opposed to each other in the z-direction. The encapsulation resin 70 fills the gap between the first semiconductor unit 1A and the second semiconductor unit 1B in the z-direction and surrounds the first semiconductor unit 1A and the second semiconductor unit 1B in the x-direction and the y-direction. That is, part of the first semiconductor unit 1A and part of the second semiconductor unit 1B are exposed from the encapsulation resin 70 in the z-direction.

As shown in FIGS. 6 and 8, the first semiconductor unit lA includes a first insulation member 10A, a first drive conductive layer 20A, a control conductive layer 40A, and multiple (four, in the present embodiment) first semiconductor elements 50A. The first semiconductor unit 1A is located on one of the opposite ends of the encapsulation resin 70 in the z-direction that is located closer to the first resin main surface 75A. That is, in the z-direction, the first semiconductor unit 1A is located closer to the cooler 200 than the second semiconductor unit 1B.

The first insulation member 10A is an electrically insulative flat substrate having a thickness-wise direction conforming to the z-direction. As viewed in the z-direction, the shape of the first insulation member 10A is a rectangle. The first insulation member 10A includes a first insulation main surface 10As and a first insulation rear surface 10Ar that face opposite sides in the z-direction. The first insulation main surface 10As and the cooler 200 face opposite sides in the z-direction. That is, the first insulation main surface 10As and the second resin main surface 75B of the encapsulation resin 70 face the same side. The first insulation rear surface 10Ar faces the cooler 200 in the z-direction. That is, the first insulation rear surface 10Ar and the first resin main surface 75A of the encapsulation resin 70 face the same side. As shown in FIG. 8, in the first semiconductor unit 1A, the first insulation rear surface 10Ar of the first insulation member 10A is exposed from the first resin main surface 75A of the encapsulation resin 70 in the z-direction. In the present embodiment, the first insulation rear surface 10Ar is flush with the first resin main surface 75A. The cooler 200 is attached to the first insulation rear surface 10Ar.

The position of the first insulation rear surface 10Ar relative to the first resin main surface 75A in the z-direction may be changed in any manner. For example, the first insulation rear surface 10Ar may project beyond the first resin main surface 75A in the z-direction. In this case, the cooler 200 is attached to the first insulation rear surface 10Ar. Thus, the cooler 200 is spaced apart from the first resin main surface 75A in the z-direction.

As shown in FIG. 6, the first insulation member 10A includes insulation side surfaces 11A to 14A. The insulation side surface 11A and the insulation side surface 12A face opposite sides in the y-direction. As viewed in the z-direction, the insulation side surfaces 11A and 12A extend in the x-direction. The insulation side surface 11A and the resin side surface 71 of the encapsulation resin 70 face the same side. The insulation side surface 12A and the resin side surface 72 of the encapsulation resin 70 face the same side. The insulation side surface 13A and the insulation side surface 14A face opposite sides in the x-direction. As viewed in the z-direction, the insulation side surfaces 13A and 14A extend in the y-direction. The insulation side surface 13A and the resin side surface 73 of the encapsulation resin 70 face the same side. The insulation side surface 14A and the resin side surface 74 of the encapsulation resin 70 face the same side.

The first drive conductive layer 20A and the control conductive layer 40A are formed on the first insulation main surface 10As of the first insulation member 10A. The conductive layers 20A and 40A are formed from, for example, Cu. The first drive conductive layer 20A and the control conductive layer 40B are spaced apart from each other and disposed on the first insulation main surface 10As.

The first drive conductive layer 20A includes a first drive wire 21 and a second drive wire 22. The first drive wire 21 and the second drive wire 22 are spaced apart from each other and disposed on the first insulation main surface 10As.

The first drive wire 21 is located on the first insulation main surface 10As at a position toward the insulation side surface 11A in the y-direction and toward the insulation side surface 14A in the x-direction. As viewed in the z-direction, the shape of the first drive conductive layer 20A is a rectangle such that the long sides extend in the x-direction and the short sides extend in the y-direction.

The first input terminal 81 is connected to the first drive wire 21. More specifically, a first conductive bonding material (not shown) such as solder or Ag paste is formed on the first drive wire 21. A conductive connection layer (not shown) is mounted on the first conductive bonding material. A second conductive bonding material (not shown) such as solder or Ag paste is formed on the connection layer. The first input terminal 81 is mounted on the second conductive bonding material. Thus, the first input terminal 81 is electrically connected to the first drive conductive layer 20A by the conductive bonding materials and the connection layer. The connection layer is formed from, for example, a metal material. In the present embodiment, the connection layer is formed from Cu. In an example, the connection layer is rod-shaped. The connection layer is, for example, a tetragonal rod. The shape of the connection layer is not limited to this and may be a round rod or a polygonal rod other than a tetragonal rod such as a triangular rod.

The first semiconductor elements 50A are mounted on the first drive wire 21. The first semiconductor elements 50A are arranged at the same position in the y-direction and spaced apart from each other in the x-direction. It is considered that the first semiconductor elements 50A are arranged at the same position in the y-direction when the largest value of deviation amounts of the first semiconductor elements 50A in the y-direction is within 10% of the dimension of the first semiconductor elements 50A in the y-direction.

In the present embodiment, the first semiconductor elements 50A are located at a center of the first drive wire 21 in the y-direction. The position of each first semiconductor element 50A on the first drive wire 21 may be changed in any manner. In an example, the first semiconductor element 50A may be located toward the insulation side surface 12A from the center of the first drive wire 21 in the y-direction.

The first semiconductor element 50A is a switching element and is, for example, a transistor formed from silicon (Si), silicon carbide (SiC), gallium nitride (GaN) or gallium arsenide (GaAs), or gallium oxide (Ga₂O₃). When the first semiconductor element 50A is formed from SiC, it is suitable for high-speed switching. In the present embodiment, each first semiconductor element 50A is an N-channel metal-oxide-semiconductor field-effect transistor (MOSFET) formed from SiC. The first semiconductor element 50A is not limited to a MOSFET and may be a field effect transistor including a metal-insulator-semiconductor FET (MISFET) or a bipolar transistor including an insulated gate bipolar transistor (IGBT). Instead of an N-channel MOSFET, the first semiconductor elements 50A may be a P-channel MOSFET.

As shown in FIG. 8, the first semiconductor elements 50A are disposed closer to the first insulation member 10A than the second semiconductor elements 50B in the z-direction. In other words, the first semiconductor elements 50A are disposed closer to the first insulation member 10A than to a second insulation member 10B between the first insulation member 10A and the second insulation member 10B in the z-direction. Each first semiconductor element 50A includes a first element main surface 50As and a first element rear surface 50Ar that face opposite sides in the z-direction. The first element main surface 50As and the first insulation main surface 10As face the same side. In other words, the first element main surface 50As and the second resin main surface 75B face the same side. The first element rear surface 50Ar and the first insulation rear surface 10Ar face the same side. In other words, the first element rear surface 50Ar and the first resin main surface 75A face the same side. A drain electrode 51A, which is an example of a first rear surface drive electrode, is formed on the first insulation rear surface 10Ar. A source electrode 52A and a gate electrode 53A, each of which is an example of a first main surface drive electrode, are formed on the first element main surface 50As. The first element rear surface 50Ar of each first semiconductor element 50A is bonded to the first drive conductive layer 20A by a conductive bonding material JA such as solder or Ag paste. Thus, the drain electrodes 51A of the first semiconductor elements 50A are electrically connected to the first drive conductive layer 20A.

The second drive wire 22 surrounds the first drive wire 21 from the vicinity of the insulation side surface 13A and the vicinity of the insulation side surface 12A. As viewed in the z-direction, the second drive wire 22 is L-shaped. The second drive wire 22 includes a main wire portion 22a extending in the x-direction and a connection wire portion 22b extending from the main wire portion 22a in the y-direction. In the present embodiment, the main wire portion 22a and the connection wire portion 22b are formed integrally with each other as a single-piece member.

The main wire portion 22a is located closer to the insulation side surface 12A than the first drive wire 21 in the y-direction. As viewed in the z-direction, the shape of the main wire portion 22a is a rectangle such that the long sides extend in the x-direction and the short sides extend in the y-direction. The main wire portion 22a includes a part that overlaps the first drive wire 21 as viewed in the y-direction. The main wire portion 22a and the first drive wire 21 are located at different positions in the x-direction. More specifically, the main wire portion 22a includes a part protruding beyond the first drive wire 21 toward the insulation side surface 13A in the x-direction. The first drive wire 21 includes a portion protruding beyond the main wire portion 22a toward the insulation side surface 14A in the x-direction.

The connection wire portion 22b extends toward the insulation side surface 11A from one of the opposite ends of the main wire portion 22a in the x-direction that is closer to the insulation side surface 13A. As viewed in the z-direction, the shape of the connection wire portion 22b is a rectangle so that the long sides extend in the y-direction and the short sides extend in the x-direction. The connection wire portion 22b is located closer to the insulation side surface 14A than the first drive wire 21. As viewed in the x-direction, the connection wire portion 22b overlaps the first drive wire 21.

The second input terminal 82 is connected to the connection wire portion 22b. Although not shown in the drawings, the connecting configuration of the connection wire portion 22b with the second input terminal 82 is the same as the connecting configuration of the first drive conductive layer 20A with the first input terminal 81.

The control conductive layer 40A includes a control wire 41A and a detection wire 42A. The control wire 41A and the detection wire 42A are spaced apart from each other and disposed on the first insulation main surface 10As. The control wire 41A and the detection wire 42A surround the main wire portion 22a of the second drive wire 22 from the insulation side surface 11A, the insulation side surface 14A, and the insulation side surface 12A. As viewed in the z-direction, each of the control wire 41A and the detection wire 42A is substantially U-shaped. The detection wire 42A is located closer to the main wire portion 22a of the second drive wire 22 than the control wire 41A. In other words, the control wire 41A surrounds the detection wire 42A from the insulation side surface 11A, the insulation side surface 14A, and the insulation side surface 12A.

The first control terminal 84A is connected to the control wire 41A. The first detection terminal 85A is connected to the detection wire 42A. Although not shown in the drawings, the bonding configuration of the control wire 41A to the first control terminal 84A and the bonding configuration of the detection wire 42A to the first detection terminal 85A are the same as the connecting configuration of the first drive conductive layer 20A to the first input terminal 81. As viewed in the z-direction, the first control terminal 84A is located closer to the insulation side surface 14A than the first detection terminal 85A. The layout positions of the first control terminal 84A and the first detection terminal 85A as viewed in the z-direction may be changed in any manner. In an example, as viewed in the z-direction, the first detection terminal 85A may be located closer to the insulation side surface 14A than the first control terminal 84A.

As shown in FIG. 6, the first semiconductor unit 1A includes wires W1 connecting the source electrode 52A of each first semiconductor element 50A to the detection wire 42A and wires W2 connecting the gate electrode 53A of each first semiconductor element 50A to the control wire 41A. The wires W1 and W2 are formed from, for example, gold (Au). Alternatively, the wires W1 and W2 may be formed from Cu or aluminum (Al). Thus, the source electrodes 52A of the first semiconductor elements 50A are electrically connected to the detection wire 42A by the wires W2. The gate electrodes 53A of the first semiconductor elements 50A are electrically connected to the control wire 41A by the wires W1.

As shown in FIGS. 7 and 8, the second semiconductor unit 1B includes the second insulation member 10B, a second drive conductive layer 20B, a control conductive layer 40B, multiple (four, in the present embodiment) second semiconductor elements 50B, and a second connection layer 60B. The second semiconductor unit 1B is located on one of the opposite ends of the encapsulation resin 70 in the z-direction that is located closer to the second resin main surface 75B. That is, the second semiconductor unit 1B is located at a position distant from the cooler 200.

The second insulation member 10B is an electrically insulative flat substrate having a thickness-wise direction conforming to the z-direction. The second insulation member 10B is spaced apart from the first insulation member 10A in the z-direction and opposed to the first insulation member 10A in the z-direction. As viewed in the z-direction, the shape of the second insulation member 10B is a rectangle. The second insulation member 10B includes a second insulation main surface 10Bs and a second insulation rear surface 10Br that face opposite sides in the z-direction. The second insulation rear surface 10Br and the cooler 200 face opposite sides in the z-direction. That is, the second insulation rear surface 10Br and the second resin main surface 75B of the encapsulation resin 70 face the same side. As shown in FIG. 8, in the second semiconductor unit 1B, the second insulation rear surface 10Br of the second insulation member 10B is exposed from the second resin main surface 75B of the encapsulation resin 70 in the z-direction. In the present embodiment, the second insulation rear surface 10Br is flush with the second resin main surface 75B. The second insulation main surface 10Bs faces the cooler 200 in the z-direction. That is, the second insulation main surface 10Bs and the first resin main surface 75A of the encapsulation resin 70 face the same side. The second insulation main surface 10Bs is opposed to the first insulation main surface 10As of the first insulation member 10A in the z-direction.

The position of the second insulation rear surface 10Br relative to the second resin main surface 75B in the z-direction may be changed in any manner. In an example, the second insulation rear surface 10Br may project beyond the second resin main surface 75B in the z-direction.

The second insulation member 10B includes insulation side surfaces 11B to 14B. The insulation side surface 11B and the insulation side surface 12B face opposite sides in the y-direction. As viewed in the z-direction, the insulation side surfaces 11B and 12B extend in the x-direction. The insulation side surface 11B and the resin side surface 71 of the encapsulation resin 70 face the same side. The insulation side surface 12B and the resin side surface 72 of the encapsulation resin 70 face the same side. Thus, the insulation side surface 11B and the insulation side surface 11A of the first insulation member 10A face the same side, and the insulation side surface 12B and the insulation side surface 12A of the first insulation member 10A face the same side. The insulation side surface 13B and the insulation side surface 14B face opposite sides in the x-direction. As viewed in the z-direction, the insulation side surfaces 13B and 14B extend in the y-direction. The insulation side surface 13B and the resin side surface 73 of the encapsulation resin 70 face the same side. The insulation side surface 14B and the resin side surface 74 of the encapsulation resin 70 face the same side. Thus, the insulation side surface 13B and the insulation side surface 13A of the first insulation member 10A face the same side, and the insulation side surface 14B and the insulation side surface 14A of the first insulation member 10A face the same side.

The second drive conductive layer 20B and the control conductive layer 40B are formed on the second insulation main surface 10Bs of the second insulation member 10B. The conductive layers 20B and 40B are formed from, for example, Cu. The second drive conductive layer 20B and the control conductive layer 40B are spaced apart from each other and disposed on the second insulation main surface 10Bs.

The second drive conductive layer 20B is located on the second insulation main surface 10Bs of the second insulation member 10B at a position toward the insulation side surface 11B in the y-direction. The second drive conductive layer 20B is located on a most part of the second insulation main surface 10Bs. As viewed in the z-direction, the shape of the second drive conductive layer 20B is a rectangle.

The output terminal 83 is connected to the second drive conductive layer 20B. The connecting configuration of the second drive conductive layer 20B to the output terminal 83 is the same as the connecting configuration of the first drive conductive layer 20A to the first input terminal 81. That is, as shown in FIG. 8, a first conductive bonding material JE1 such as solder or Ag paste is formed on the second drive conductive layer 20B. A conductive connection layer 30 is mounted on the first conductive bonding material JE1. A second conductive bonding material JE2 such as solder or Ag paste is formed on the connection layer 30. The output terminal 83 is mounted on the second conductive bonding material JE2. Thus, the output terminal 83 is electrically connected to the second drive conductive layer 20B by the conductive bonding materials JE1 and JE2 and the connection layer 30. The connection layer 30 is formed from, for example, a metal material. In the present embodiment, the connection layer 30 is formed from Cu. In an example, the connection layer 30 is rod-shaped. The connection layer 30 is, for example, a tetragonal rod. The shape of the connection layer 30 is not limited to this and may be a round rod or a polygonal rod other than a tetragonal rod, such as a triangular rod.

As shown in FIG. 7, the second semiconductor elements 50B are mounted on the second drive conductive layer 20B. In the present embodiment, the second semiconductor elements 50B are located on the second drive conductive layer 20B at a position toward the insulation side surface 12B and toward the insulation side surface 13B. More specifically, the second semiconductor elements 50B are located in a region R of the second drive conductive layer 20B that is opposed to the main wire portion 22a of the second drive wire 22 of the first semiconductor unit lA in the z-direction.

The second semiconductor elements 50B are arranged at the same position in the y-direction and spaced apart from each other in the x-direction. It is considered that the second semiconductor elements 50B are arranged at the same position in the y-direction when the largest value of deviation amounts of the second semiconductor elements 50B in the y-direction is within 10% of the dimension of the second semiconductor elements 50B in the y-direction. As shown in FIGS. 6 to 8, the second semiconductor elements 50B are spaced apart from the first semiconductor elements 50A in the y-direction. As viewed in the z-direction, the first semiconductor elements 50A and the second semiconductor elements 50B are located at different locations in the x-direction. The first semiconductor elements 50A are offset from the second semiconductor elements 50B toward the resin side surface 74. As viewed in the y-direction, the first semiconductor elements 50A partially overlap the second semiconductor elements 50B.

Each second semiconductor element 50B is a transistor formed from, for example, Si, SiC, GaN or GaAs, or Ga2O3. When the second semiconductor element 50B is formed from SiC, it is suitable for high-speed switching. In the present embodiment, the second semiconductor element 50B is an N-channel MOSFET formed from SiC. The second semiconductor element 50B is not limited to a MOSFET and may be a field effect transistor including a MISFET or a bipolar transistor including IGBT. Instead of an N-channel MOSFET, the second semiconductor element 50B may be a P-channel MOSFET.

As shown in FIG. 8, the second semiconductor elements 50B are located closer to the second insulation member 10B than the first semiconductor elements 50A in the z-direction. In other words, the second semiconductor elements 50B are located closer to the second insulation member 10B than to the first insulation member 10A between the first insulation member 10A and the second insulation member 10B in the z-direction. The second semiconductor elements 50B include a second element main surface 50Bs and a second element rear surface 50Br that face opposite sides in the z-direction. The second element main surface 50Bs and the second insulation main surface 10Bs face the same side. In other words, the second element main surface 50Bs and the first resin main surface 75A face the same side. The second element rear surface 50Br and the second insulation rear surface 10Br face the same side. In other words, the second element rear surface 50Br and the second resin main surface 75B face the same side. As shown in FIG. 8, the second semiconductor elements 50B and the first semiconductor elements 50A are inversely arranged in the z-direction. A drain electrode 51B, which is an example of a second rear surface drive electrode, is formed on the second insulation rear surface 10Br. A source electrode 52B and a gate electrode 53B, each of which is an example of a second main surface drive electrode, are formed on the second element main surface 50Bs. The second element rear surfaces 50Br of the second semiconductor elements 50B are bonded to the second drive conductive layer 20B by a conductive bonding material JB such as solder or Ag paste. Thus, the drain electrodes 51B of the second semiconductor elements 50B are electrically connected to the second drive conductive layer 20B.

As shown in FIG. 7, the control conductive layer 40B is located on the second insulation main surface 10Bs of the second insulation member 10B between the second drive conductive layer 20B and the insulation side surface 12B in the y-direction. The control conductive layer 40B includes a control wire 41B and a detection wire 42B. As viewed in the z-direction, each of the control wire 41B and the detection wire 42B is belt-shaped and extends in the x-direction. The control wire 41B and the detection wire 42B are located at the same position in the x-direction and spaced apart from each other in the y-direction. The control wire 41B is located closer to the second drive conductive layer 20B than the detection wire 42B.

The second control terminal 84B is connected to the control wire 41B. The second detection terminal 85B is connected to the detection wire 42B. Although not shown in the drawings, the bonding configuration of the control wire 41B to the second control terminal 84B and the bonding configuration of the detection wire 42B to the second detection terminal 85B are the same as the connecting configuration of the first drive conductive layer 20A to the first input terminal 81. As viewed in the z-direction, the second detection terminal 85B is located closer to the insulation side surface 13A than the second control terminal 84B. The layout positions of the second control terminal 84B and the second detection terminal 85B as viewed in the z-direction may be changed in any manner. In an example, as viewed in the z-direction, the second control terminal 84B may be located closer to the insulation side surface 13A than the second detection terminal 85B.

As shown in FIG. 7, the second semiconductor unit 1B includes wires W3 connecting the source electrodes 52B of the second semiconductor elements 50B to the detection wire 42B and wires W4 connecting the gate electrodes 53B of the second semiconductor elements 50B to the control wire 41B. The wires W3 and W4 are formed from, for example, Au. Alternatively, the wires W3 and W4 may be formed from Cu or Al. Thus, the source electrodes 52B of the second semiconductor elements 50B are electrically connected to the detection wire 42B. The gate electrodes 53B of the second semiconductor elements 50B are electrically connected to the control wire 41B.

As shown in FIG. 8, the source electrodes 52A of the first semiconductor elements 50A are electrically connected to the second drive conductive layer 20B of the second semiconductor unit 1B. More specifically, a first conductive bonding material JA1 such as solder or Ag paste is applied to the source electrodes 52A. A conducive first connection layer 60A is mounted on the first conductive bonding material JA1. A second conductive bonding material JA2 such as solder or Ag paste is applied to a portion of the second drive wire 22 opposed to the first connection layer 60A in the z-direction. The second conductive bonding material JA2 is in contact with the first connection layer 60A. More specifically, the first connection layer 60A is bonded to the source electrodes 52A and the second drive conductive layer 20B by the conductive bonding materials JA1 and JA2. Thus, the source electrodes 52A are electrically connected to the second drive conductive layer 20B by the conductive bonding materials JA1 and JA2 and the first connection layer 60A.

The first connection layer 60A is formed from, for example, a metal material. In the present embodiment, the first connection layer 60A is formed from Cu. In an example, the first connection layer 60A is rod-shaped. The first connection layer 60A is, for example, a tetragonal rod. The shape of the first connection layer 60A is not limited to this and may be a round rod or a polygonal rod other than a tetragonal rod such as a triangular rod. As shown in FIG. 8, in the present embodiment, the thickness of the first connection layer 60A (dimension of the first connection layer 60A in the z-direction) is greater than the thickness of the first semiconductor element 50A (dimension of the first semiconductor element 50A in the z-direction).

As shown in FIG. 8, the source electrodes 52B of the second semiconductor elements 50B are electrically connected to the second drive wire 22 of the first drive conductive layer 20A of the first semiconductor unit 1A. More specifically, a first conductive bonding material JB1 such as solder or Ag paste is applied to the source electrodes 52B. The second connection layer 60B, which is conductive, is mounted on the first conductive bonding material JB1. A second conductive bonding material JB2 such as solder or Ag paste is applied to a portion of the second drive wire 22 opposed to the second connection layer 60B in the z-direction. The second conductive bonding material JB2 is in contact with the second connection layer 60B. That is, the second connection layer 60B is bonded to the source electrodes 52B and the second drive wire 22 by the conductive bonding materials JB1 and JB2. Thus, the source electrodes 52B are electrically connected to the second drive wire 22 by the conductive bonding materials JB1 and JB2 and the second connection layer 60B.

The second connection layer 60B is formed from, for example, a metal material. In the present embodiment, the first connection layer 60A is formed from Cu. In an example, the second connection layer 60B is rod-shaped. The second connection layer 60B is, for example, a tetragonal rod. The shape of the second connection layer 60B is not limited to this and may be a round rod or a polygonal rod other than a tetragonal rod such as a triangular rod. As shown in FIG. 8, in the present embodiment, the thickness of the second connection layer 60B (dimension of the second connection layer 60B in the z-direction) is greater than the thickness of the second semiconductor element 50B (dimension of the second semiconductor element 50B in the z-direction).

The thicknesses of the first connection layer 60A and the second connection layer 60B may be changed in any manner. In an example, the thickness of the first connection layer 60A may be less than or equal to the thickness of the first semiconductor element 50A. The thickness of the second connection layer 60B may be less than or equal to the thickness of the second semiconductor element 50B.

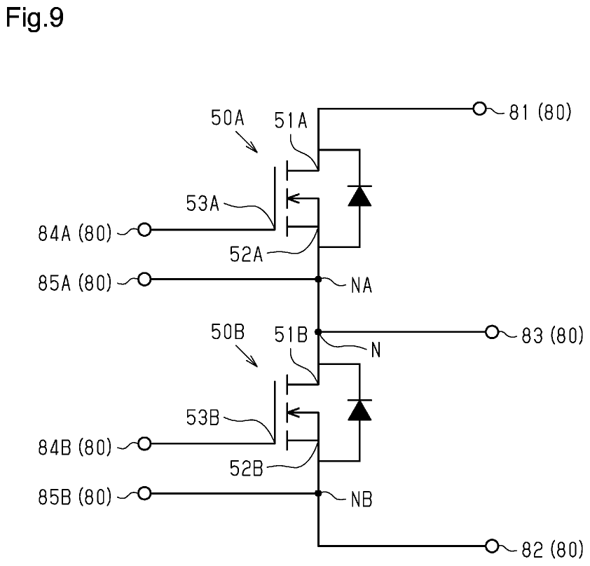

The circuit configuration of the semiconductor device 1, which is configured as described above, includes a half-bridge inverter circuit in which the four first semiconductor elements 50A that are connected in parallel to each other are connected in series to the four second semiconductor elements 50B that are connected in parallel to each other. FIG. 9 shows an example of the inverter circuit of the semiconductor device 1. In FIG. 9, for the sake of convenience, the first semiconductor element 50A is shown as one of the four first semiconductor elements 50A connected in parallel to each other, and the second semiconductor element 50B is shown as one of the four second semiconductor elements 50B connected in parallel to each other.

As shown in FIG. 9, the drain electrode 51A of the first semiconductor element 50A is electrically connected to the first input terminal 81. The source electrode 52A of the first semiconductor element 50A is electrically connected to the drain electrode 51B of the second semiconductor element 50B. The output terminal 83 is connected to a node N of the source electrode 52A of the first semiconductor element 50A and the drain electrode 51B of the second semiconductor element 50B. The source electrode 52B of the second semiconductor element 50B is electrically connected to the second input terminal 82.

The gate electrode 53A of the first semiconductor element 50A is connected to the first control terminal 84A. The gate electrode 53B of the second semiconductor element 50B is connected to the second control terminal 84B. The first detection terminal 85A is connected to a node NA located between the source electrode 52A of the first semiconductor element 50A and the node N. The second detection terminal 85B is connected to a node NB located between the source electrode 52B of the second semiconductor element 50B and the second input terminal 82.

The heat dissipation structure of the semiconductor device 1 will now be described with reference to FIGS. 7 and 8.

As shown in FIG. 8, the semiconductor device 1 includes a connection member 90 that connects the first drive conductive layer 20A and the second drive conductive layer 20B. In the present embodiment, the connection member 90 is bonded to the first drive conductive layer 20A and the second drive conductive layer 20B, for example, by adhesive (not shown).

The connection member 90 has a higher thermal conductivity than the encapsulation resin 70. The thermal conductivity of the connection member 90 is higher than the thermal conductivity of air. Preferably, the thermal conductivity of the connection member 90 is greater than or equal to 10 W/mK. The connection member 90 is formed from an electrically insulative material and, for example, is formed from a material having a superior thermal conductivity such as a ceramic including Si, alumina, and aluminum nitride. In the present embodiment, the connection member 90 is formed from a ceramic. The connection member 90 assists heat dissipation of semiconductor elements of a semiconductor unit to which the cooler 200 is not attached (in the present embodiment, the second semiconductor elements 50B of the second semiconductor unit 1B). In the present embodiment, the connection member 90 forms a heat conduction path extending between the second drive wire 22 of the first drive conductive layer 20A and the second drive conductive layer 20B.

The connection member 90 and the control conductive layer 40B are located at opposite sides of the second semiconductor elements 50B in the y-direction. In the present embodiment, the connection member 90 is located between the first semiconductor elements 50A and the second semiconductor elements 50B in the y-direction. More specifically, the connection member 90 is located closer to the second semiconductor elements 50B than to the first semiconductor elements 50A in the y-direction. The connection member 90 is disposed adjacent to the second semiconductor elements 50B in the y-direction. As shown in FIG. 7, the connection member 90 is disposed in the region R.

As shown in FIG. 7, the connection member 90 extends in the x-direction so as to oppose all of the second semiconductor elements 50B in the y-direction. That is, the connection member 90 is disposed adjacent to all of the second semiconductor elements 50B in the y-direction. As viewed in the z-direction, the shape of the connection member 90 is a rectangle such that the long sides extend in the x-direction and the short sides extend in the y-direction. The connection member 90 is smaller in dimension in the y-direction than each second semiconductor element 50B. As shown in FIGS. 7 and 8, in the present embodiment, the connection member 90 is formed of a flat block having a thickness-wise direction conforming to the y-direction.

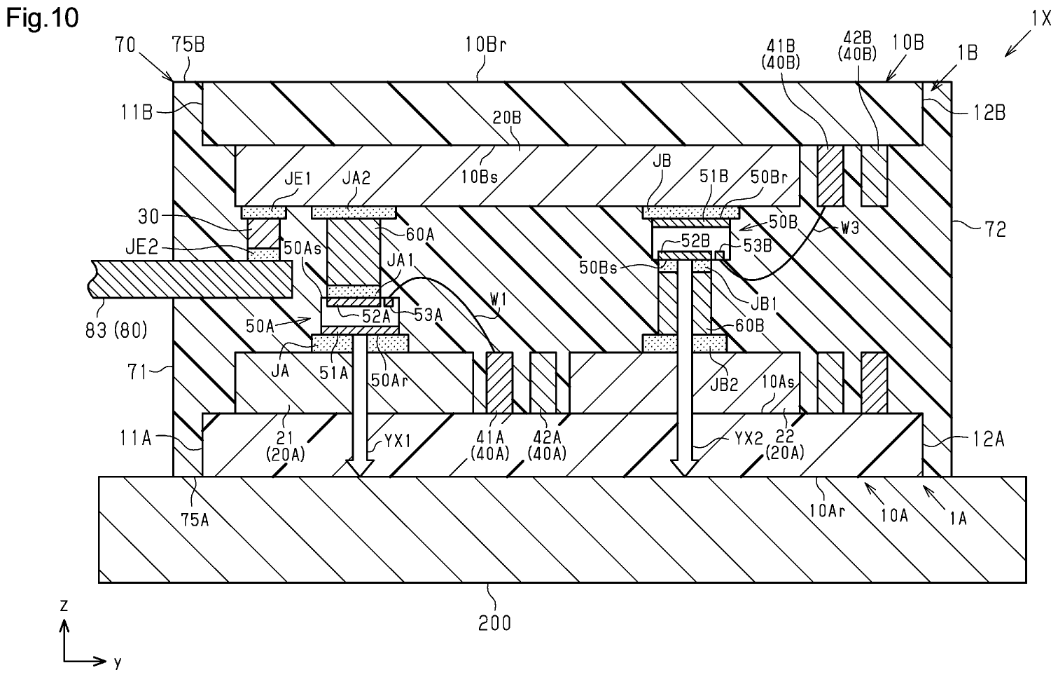

The operation of the present embodiment will now be described with reference to FIGS. 8 and 10.

FIG. 10 shows a cross-sectional structure of a comparative example of a semiconductor device 1X. The semiconductor device 1X of the comparative example has a structure that is obtained by omitting the connection member 90 from the semiconductor device 1 of the present embodiment. In the semiconductor device 1X of the comparative example, the same reference characters are given to those components that are the same as the corresponding components of the semiconductor device 1. Such components will not be described.

In the semiconductor device 1X, when the first semiconductor elements 50A and the second semiconductor elements 50B are driven, the first semiconductor elements 50A and the second semiconductor elements 50B generate heat. The cooler 200 is attached to the first insulation member 10A of the first semiconductor unit 1A. Therefore, the heat of the first semiconductor elements 50A transfers to the cooler 200 through the conductive bonding material JA, the first drive wire 21 of the first drive conductive layer 20A, and the first insulation member 10A as indicated by arrow YX1 shown in FIG. 10. The cooler 200 is not attached to the second insulation member 10B of the second semiconductor unit 1B. Therefore, the heat of the second semiconductor elements 50B transfers to the cooler 200 through the first conductive bonding material JB1, the second connection layer 60B, the second conductive bonding material JB2, the second drive wire 22 of the first drive conductive layer 20A, and the first insulation member 10A as indicated by arrow YX2 shown in FIG. 10. Thus, the thermal resistance from the second semiconductor elements 50B to the cooler 200 is greater than the thermal resistance from the first semiconductor elements 50A to the cooler 200. As a result, the second semiconductor elements 50B do not readily dissipate heat as compared to the first semiconductor elements 50A and tends to increase in temperature as compared to the first semiconductor elements 50A.

In the semiconductor device 1 of the present embodiment, when the first semiconductor elements 50A and the second semiconductor elements 50B are driven, heat of the first semiconductor elements 50A transfers to the cooler 200 through the conductive bonding material JA, the first drive wire 21 of the first drive conductive layer 20A, and the first insulation member 10A as indicated by arrow Y1 shown in FIG. 8.

Also, heat of the second semiconductor elements 50B transfers to the cooler 200 through two heat conduction paths. More specifically, the heat of the second semiconductor elements 50B transfers to the cooler 200 through the first conductive bonding material JB1, the second connection layer 60B, the second conductive bonding material JB2, the second drive wire 22 of the first drive conductive layer 20A, and the first insulation member 10A as indicated by arrow Y2 shown in FIG. 8. In addition, the heat of the second semiconductor elements 50B transfers to the cooler 200 through the conductive bonding material JB, the second drive conductive layer 20B, the connection member 90, the second drive wire 22 of the first drive conductive layer 20A, and the first insulation member 10A as indicated by arrow Y3 shown in FIG. 8. Thus, the heat of the second semiconductor elements 50B transfers to the cooler 200 through the two paths, namely, the heat conduction path indicated by arrow Y2 and the heat conduction oath indicated by arrow Y3. This limits increases in the difference between the thermal resistance from the second semiconductor elements 50B to the cooler 200 and the thermal resistance from the first semiconductor elements 50A to the cooler 200. The second semiconductor elements 50B and the first semiconductor elements 50A have a similar heat dissipation efficiency. This reduces situations in which the second semiconductor elements 50B tend to increase in temperature as compared to the first semiconductor elements 50A.

The semiconductor device 1 of the present embodiment has the following advantages.

(1) The semiconductor device 1 includes the connection member 90, which connects the first drive conductive layer 20A and the second drive conductive layer 20B, and the encapsulation resin 70, which encapsulates the first semiconductor elements 50A, the second semiconductor elements 50B, and the connection member 90. The connection member 90 forms a heat conduction path from the second semiconductor elements 50B toward the cooler 200. The thermal conductivity of the connection member 90 is higher than the thermal conductivity of the encapsulation resin 70. This structure increases the heat conduction path extending between the cooler 200 and the second semiconductor elements 50B, which are located farther from the cooler 200 than the first semiconductor elements 50A. Thus, the semiconductor device 1 limits increases in the difference between the thermal resistance from the first semiconductor elements 50A to the cooler 200 and the thermal resistance from the second semiconductor elements 50B to the cooler 200. As a result, when the first semiconductor elements 50A and the second semiconductor elements 50B are driven, the temperature of the second semiconductor elements 50B does not excessively increase as compared to the temperature of the first semiconductor elements 50A. Thus, the semiconductor device 1 provides a sufficient performance.

(2) For example, if the connection member 90 is connected to the second insulation main surface 10Bs of the second insulation member 10B, the heat of the second semiconductor elements 50B is conducted to the second drive conductive layer 20B and the second insulation member 10B and again conducted to the second drive conductive layer 20B and transferred to the connection member 90. This extends the heat transfer path from the second semiconductor elements 50B to the connection member 90.

In this regard, in the present embodiment, the connection member 90 is connected to the second drive conductive layer 20B. In this structure, the heat of the second semiconductor elements 50B transfers from the second drive conductive layer 20B to the connection member 90. Thus, the heat conduction path shortens. This facilitates transfer of the heat from the second semiconductor elements 50B to the connection member 90.

(3) As viewed in the z-direction, the connection member 90 is disposed closer to the second semiconductor elements 50B than to the first semiconductor elements 50A. In this structure, the heat of the second semiconductor elements 50B transfers to the connection member 90 more easily than the heat of the first semiconductor elements 50A. This reduces situations in which the second semiconductor elements 50B tend to increase in temperature as compared to the first semiconductor elements 50A.

(4) The source electrode 52B is formed on the second element main surface 50Bs of the second semiconductor element 50B and is connected to the second drive wire 22 of the first drive conductive layer 20A by the second connection layer 60B. In this structure, the heat of the second semiconductor elements 50B transfers to the cooler 200 through the second connection layer 60B, the second drive wire 22, and the first insulation member 10A. This hinders an excessive increase in the temperature of the second semiconductor elements 50B.

The source electrode 52A is formed on the first element main surface 50As of the first semiconductor element 50A and is connected to the second drive conductive layer 20B by the first connection layer 60A. In this structure, the heat of the first semiconductor elements 50A transfers to the first connection layer 60A, the second drive conductive layer 20B, and the second insulation member 10B. This hinders an excessive increase in the temperature of the first semiconductor elements 50A.

(5) As viewed in the y-direction, the connection member 90 overlaps all of the second semiconductor elements 50B. In this structure, the heat of each second semiconductor element 50B transfers to the connection member 90, thereby limiting variations in the temperature of the second semiconductor elements 50B.

(6) The connection member 90 is disposed adjacent to all of the second semiconductor elements 50B in the y-direction. This structure facilitates transfer of heat from each second semiconductor element 50B to the connection member 90. As a result, the temperature of each second semiconductor element 50B is hindered from excessively increasing.

(7) If the connection member 90 is arranged between the second semiconductor elements 50B and the control conductive layer 40B formed on the second insulation main surface 10Bs of the second insulation member 10B, the wires W3 for connecting the second semiconductor elements 50B to the control wire 41B and the wires W4 for connecting the second semiconductor elements 50B to the detection wire 42B need to be formed to avoid the connection member 90. This may result in extension of the wires W3 and W4 or hamper formation of the wires W3 and W4.

In this regard, in the present embodiment, the connection member 90 is disposed at the opposite side from the control conductive layer 40B. In this structure, the wires W3 and W4 do not need to be formed to avoid the connection member 90. Thus, the wires W3 and W4 are readily formed and may be shortened.

(8) Each of the first insulation member 10A and the second insulation member 10B is formed from a ceramic. In this structure, the heat of the first semiconductor elements 50A and the second semiconductor elements 50B readily transfers from the first insulation member 10A to the cooler 200. Further, the heat of the first semiconductor elements 50A and the second semiconductor elements 50B readily dissipates from the second insulation member 10B to the exterior.

(9) The first input terminal 81, the second input terminal 82, and the output terminal 83 project from the resin side surface 74 of the encapsulation resin 70. In this structure, for example, when the semiconductor device 1 is mounted on a mount substrate and a snubber capacitor is mounted on the mount substrate, a wire that connects the semiconductor device 1 to the snubber capacitor is simply formed.

(10) The connection member 90 is smaller in dimension in the y-direction than the second semiconductor elements 50B. This structure limits increases in the dimension of the second drive wire 22 of the first drive conductive layer 20A in the y-direction, thereby limiting increases in the dimension of the semiconductor device 1 in the y-direction.

### MODIFIED EXAMPLES

The embodiment exemplifies, without any intention to limit, an applicable form of a semiconductor device according to the present disclosure. The semiconductor device according to the present disclosure may be applicable to forms differing from the above embodiment. In an example of such a form, the structure of the embodiment is partially replaced, changed, or omitted, or a further structure is added to the above embodiment. The modified examples described below may be combined with one another as long as there is no technical inconsistency. In the modified examples, the same reference characters are given to those components that are the same as the corresponding components of the above embodiment. Such components will not be described in detail.

In the embodiment, the dimensions of the encapsulation resin 70 in the x-direction and the y-direction may be changed in any manner. In an example, the insulation side surfaces 11A to 14A of the first insulation member 10A may be exposed from the encapsulation resin 70. The insulation side surfaces 11B to 14B of the second insulation member 10B may be exposed from the encapsulation resin 70.

In the embodiment, at least one of the adhesive applied between the connection member 90 and the first drive conductive layer 20A and the adhesive applied between the connection member 90 and the second drive conductive layer 20B may be omitted. For example, when the adhesive applied between the connection member 90 and the first drive conductive layer 20A is omitted, the connection member 90 is in contact with the first drive conductive layer 20A. For example, when the adhesive applied between the connection member 90 and the second drive conductive layer 20B is omitted, the connection member 90 is in contact with the second drive conductive layer 20B.

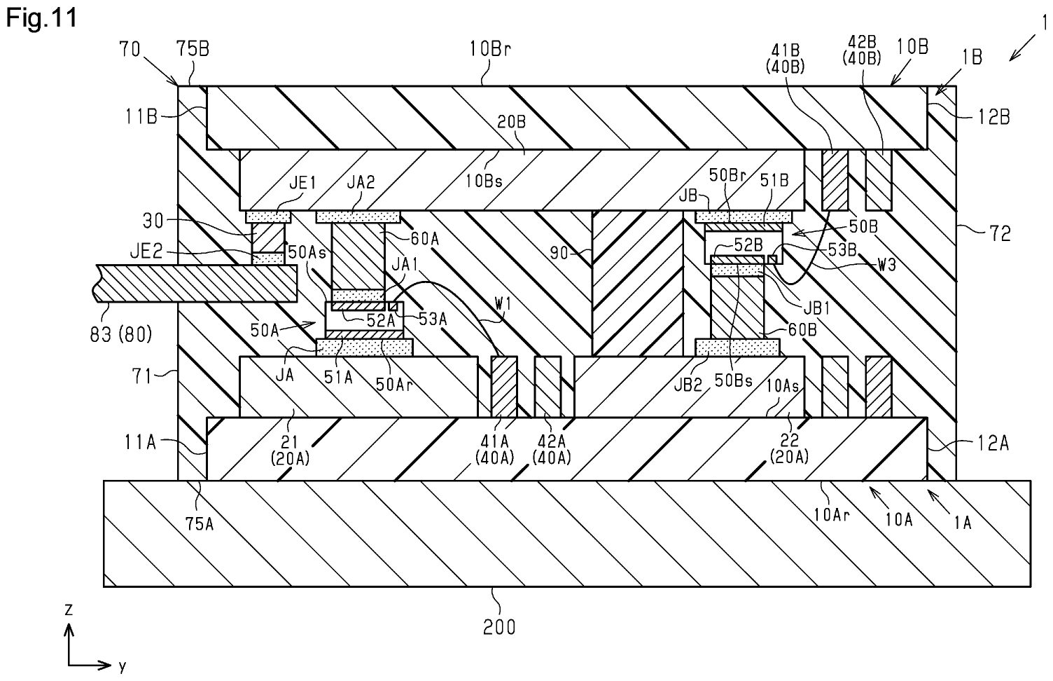

In the embodiment, the dimension of the connection member 90 in the y-direction may be changed in any manner. In an example, as shown in FIG. 11, the dimension of the connection member 90 in the y-direction may be increased from the dimension of the connection member 90 of the embodiment in the y-direction. In this case, the second semiconductor elements 50B are disposed at one of the opposite ends of the second drive conductive layer 20B in the y-direction that is located closer to the insulation side surface 12B. As a result, in the region R (refer to FIG. 7), the space for the connection member 90 is enlarged in the y-direction. Thus, even when the connection member 90 is increased in size in the y-direction, the connection member 90 is accommodated in the region R.

In this structure, the volume of the connection member 90 is increased to facilitate transfer of the heat from the second semiconductor elements 50B to the cooler 200 through the connection member 90. This further reduces situations in which the second semiconductor elements 50B tend to increase in temperature as compared to the first semiconductor elements 50A.

In the embodiment, the dimension of the connection member 90 in the x-direction may be changed in any manner. The dimension of the connection member 90 in the x-direction may be such that the connection member 90 is opposed to some of the second semiconductor elements 50B in the y-direction.

In the embodiment, the shape of the connection member 90 as viewed in the z-direction may be changed in any manner. The shape of the connection member 90 as viewed in the z-direction may be changed, for example, as the following (A) to (C).

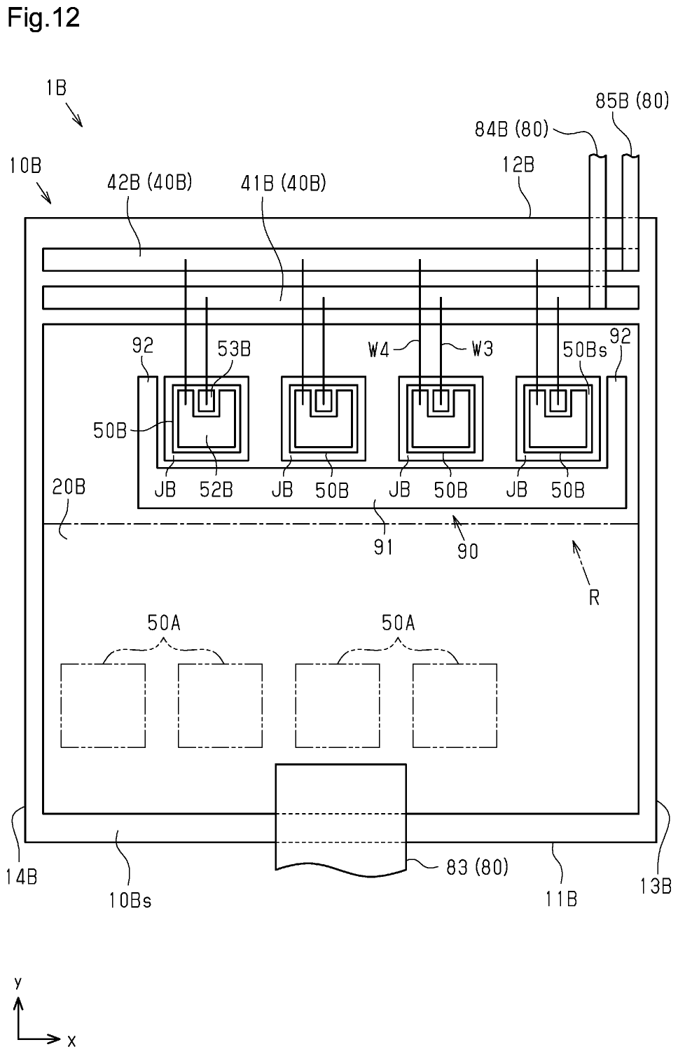

(A) As shown in FIG. 12, the connection member 90 includes a main opposing wall 91 and end opposing walls 92. The main opposing wall 91 is opposed to all of the second semiconductor elements 50B in the y-direction. The end opposing walls 92 are opposed in the x-direction to ones of the second semiconductor elements 50B that are located at opposite ends in the x-direction. In the illustrated example, the connection member 90 is a single-piece component in which the main opposing wall 91 is formed integrally with the end opposing walls 92. The main opposing wall 91 is disposed adjacent to the second semiconductor elements 50B in the y-direction and extends in the x-direction. The end opposing walls 92 extend in the y-direction from opposite ends of the main opposing wall 91 in the x-direction. The end opposing walls 92 are disposed adjacent, in the x-direction, to ones of the second semiconductor elements 50B that are located at opposite ends in the x-direction. In the illustrated example, the end opposing walls 92 overlap all of the second semiconductor elements 50B as viewed in the x-direction.

In this structure, the volume of the connection member 90 is increased as compared to a structure in which the end opposing walls 92 are omitted from the connection member 90. This facilitates transfer of heat from the second semiconductor elements 50B to the connection member 90 when the second semiconductor elements 50B are driven. In the modified example shown in FIG. 12, in the connection member 90, the main opposing wall 91 may be separated from at least one of the two end opposing walls 92.

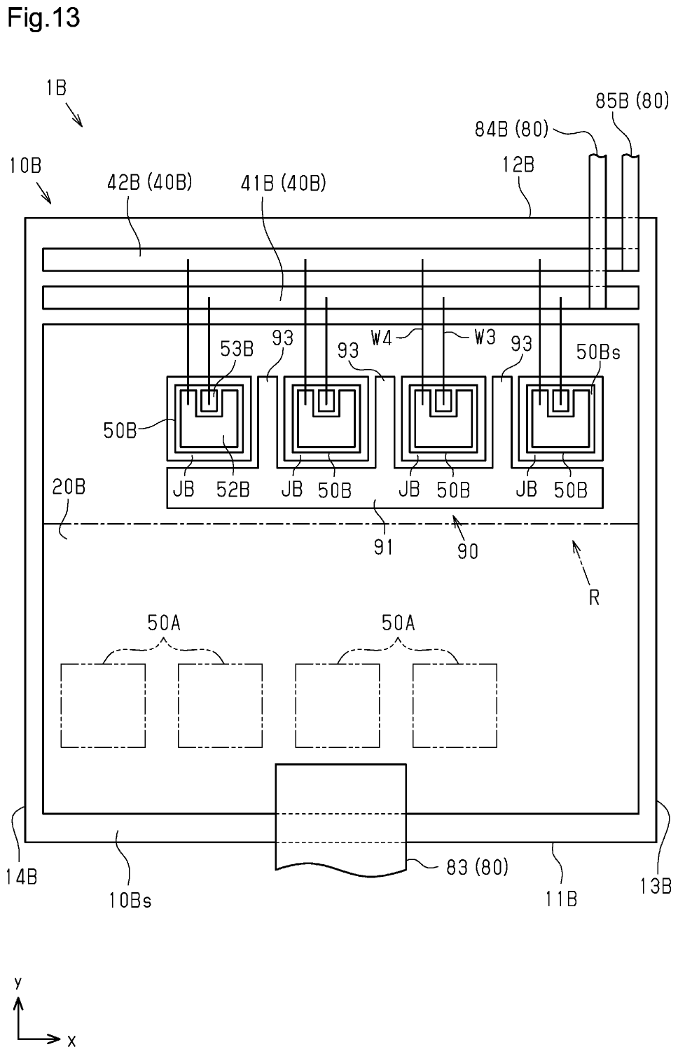

(B) As shown in FIG. 13, the connection member 90 includes a main opposing wall 91 and multiple (three, in the illustrated example) intermediate opposing walls 93. The main opposing wall 91 is opposed to all of the second semiconductor elements 50B in the y-direction. The intermediate opposing walls 93 are disposed between adjacent ones of the second semiconductor elements 50B in the x-direction. In the illustrated example, the connection member 90 is a single-piece component in which the main opposing wall 91 is formed integrally with the intermediate opposing walls 93. The main opposing wall 91 is disposed adjacent to the second semiconductor elements 50B in the y-direction and extends in the x-direction. The intermediate opposing walls 93 extend from the main opposing wall 91 in the y-direction. Each intermediate opposing wall 93 is opposed to the second semiconductor elements 50B in the x-direction. The intermediate opposing walls 93 overlap all of the second semiconductor elements 50B as viewed in the x-direction.

In this structure, the volume of the connection member 90 is increased as compared to a structure in which the intermediate opposing walls 93 are omitted from the connection member 90. This facilitates transfer of heat from the second semiconductor elements 50B to the connection member 90 when the second semiconductor elements 50B are driven. In the modified example shown in FIG. 13, in the connection member 90, the main opposing wall 91 may be separated from at least one of the three intermediate opposing walls 93.

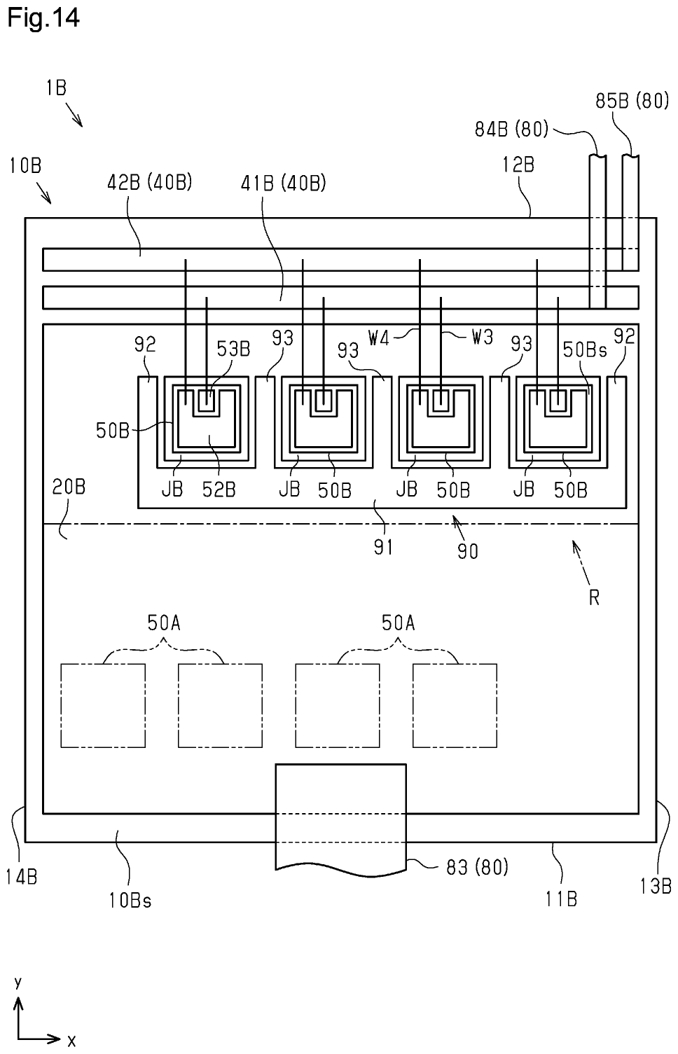

(C) As shown in FIG. 14, the connection member 90 includes the main opposing wall 91, which is opposed to all of the second semiconductor elements 50B in the y-direction, the end opposing walls 92, which are opposed in the x-direction to ones of the second semiconductor elements 50B that are located at opposite ends in the x-direction, and the intermediate opposing walls 93, which are disposed between adjacent ones of the second semiconductor elements 50B in the x-direction. In the illustrated example, the connection member 90 is a single-piece component in which the main opposing wall 91, the end opposing walls 92, and the intermediate opposing walls 93 are formed integrally with each other. The main opposing wall 91 is disposed adjacent to the second semiconductor elements 50B in the y-direction and extends in the x-direction. The end opposing walls 92 extend in the y-direction from opposite ends of the main opposing wall 91 in the x-direction. The end opposing walls 92 are disposed adjacent, in the x-direction, to ones of the second semiconductor elements 50B that are located at opposite ends in the x-direction. In the illustrated example, the end opposing walls 92 overlap all of the second semiconductor elements 50B as viewed in the x-direction. The intermediate opposing walls 93 extend from the main opposing wall 91 in the y-direction. Each intermediate opposing wall 93 is opposed to the second semiconductor elements 50B in the x-direction. The intermediate opposing walls 93 overlap all of the second semiconductor elements 50B as viewed in the x-direction.

In this structure, the volume of the connection member 90 is increased as compared to a structure in which at least one of the end opposing walls 92 and the intermediate opposing walls 93 are omitted from the connection member 90. This facilitates transfer of heat from the second semiconductor elements 50B to the connection member 90 when the second semiconductor elements 50B are driven.

In the modified example shown in FIG. 14, in the connection member 90, the main opposing wall 91 may be separated from at least one of the two end opposing walls 92. In the connection member 90, the main opposing wall 91 may be separated from at least one of the three intermediate opposing walls 93. In the connection member 90, the main opposing wall 91, at least one of the two end opposing walls 92, and at least one of the three intermediate opposing walls 93 may be separated from each other.

In (A) to (C), the dimension of each end opposing wall 92 in the y-direction may be changed in any manner. In an example, the end opposing walls 92 may overlap part of the second semiconductor elements 50B as viewed in the x-direction. In addition, as viewed in the z-direction, the end opposing walls 92 may protrude beyond the second semiconductor elements 50B toward the insulation side surface 12B in the y-direction.

In (B) and (C), the dimension of each intermediate opposing wall 93 in the y-direction may be changed in any manner. In an example, the intermediate opposing walls 93 may overlap part of the second semiconductor elements 50B as viewed in the x-direction. In addition, as viewed in the z-direction, the intermediate opposing walls 93 may protrude beyond the second semiconductor elements 50B toward the insulation side surface 12B in the y-direction.

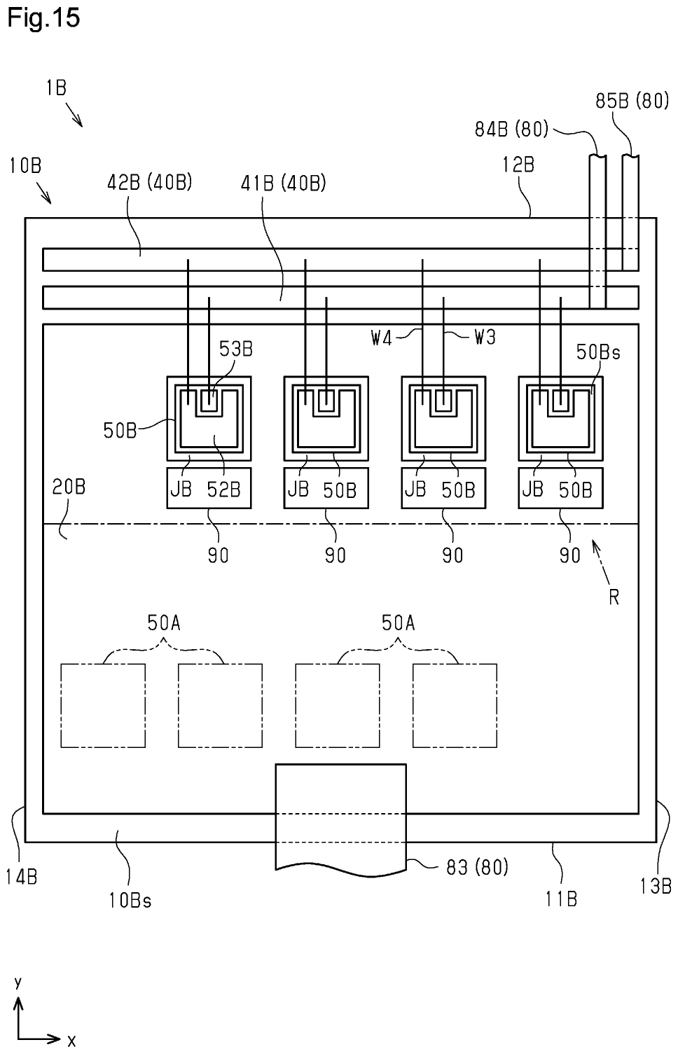

In the embodiment, the second semiconductor elements 50B share the connection member 90. Instead, for example, as shown in FIG. 15, each second semiconductor element 50B may be provided with one connection member 90. Each connection member 90 is opposed to one of the second semiconductor elements 50B corresponding to the connection member 90 in the y-direction. More specifically, each connection member 90 is disposed adjacent to one of the second semiconductor elements 50B corresponding to the connection member 90 in the y-direction.

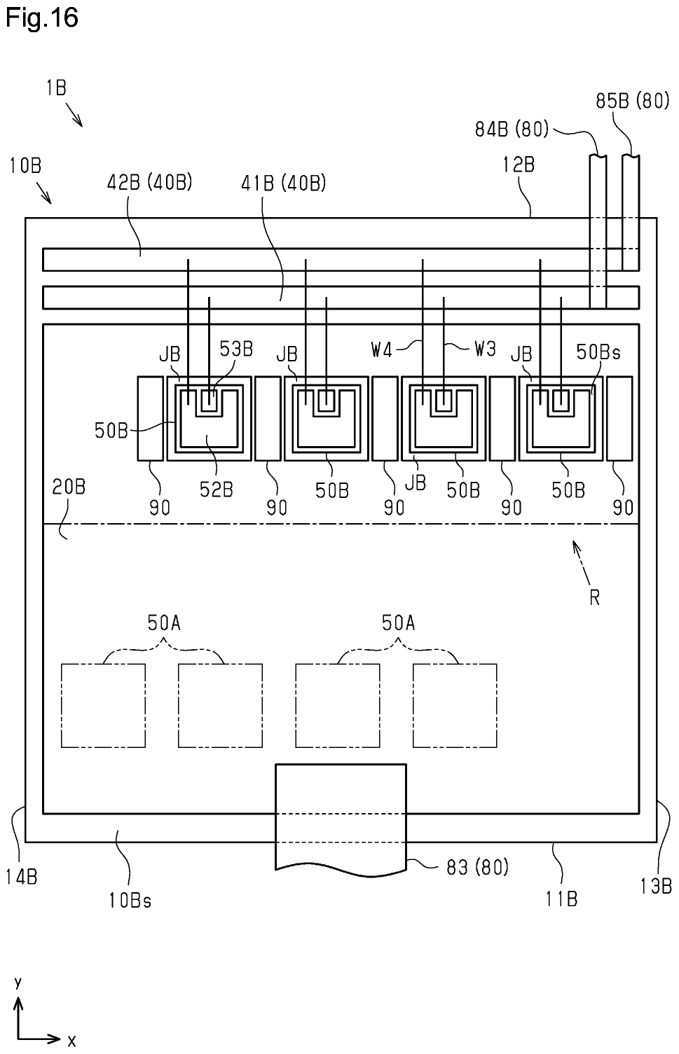

In the modified example shown in FIG. 15, the layout positions of the connection members 90 relative to the second semiconductor elements 50B may be changed in any manner. In an example, as shown in FIG. 16, the connection members 90 may be disposed between adjacent ones of the second semiconductor elements 50B in the x-direction. In addition, for each of the second semiconductor elements 50B located at opposite ends in the x-direction, the connection members 90 may be arranged at a side of the second semiconductor element 50B opposite from its adjacent second semiconductor element 50B in the x-direction. That is, the connection members 90 are disposed at opposite sides, in the x-direction, of the second semiconductor elements 50B that are located at opposite ends in the x-direction. As viewed in the z-direction, the connection members 90 extend in the y-direction. In the illustrated example, the connection members 90 overlap the entirety of the second semiconductor elements 50B as viewed in the x-direction.

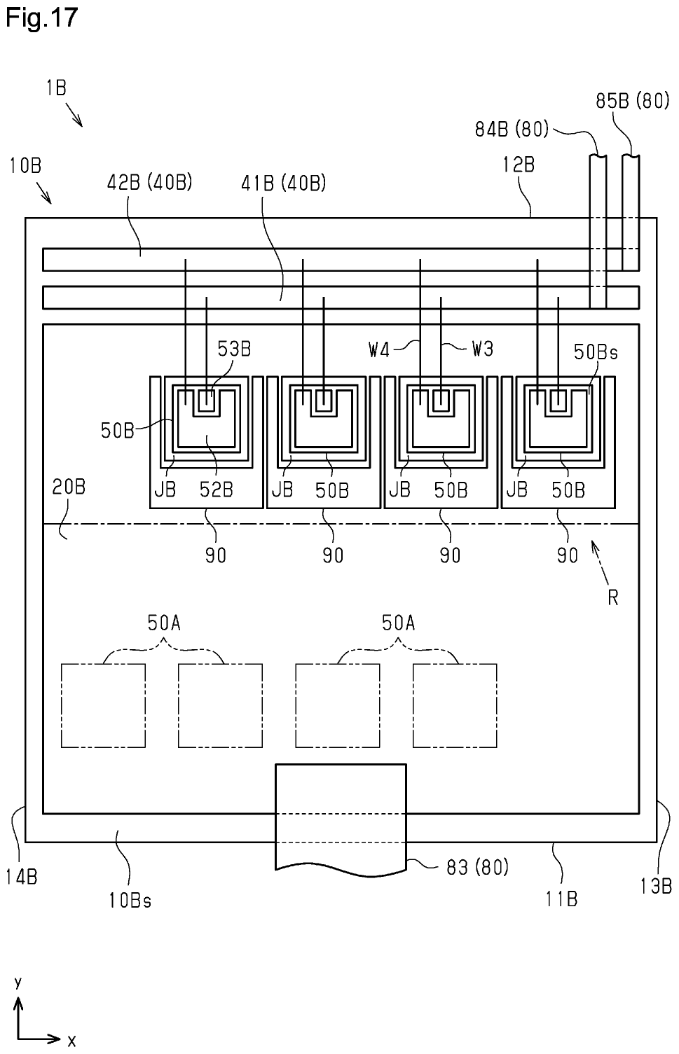

In the modified example shown in FIG. 15, the shape of the connection members 90 as viewed in the z-direction may be changed in any manner. In an example, as shown in FIG. 17, each connection member 90 may surround the second semiconductor element 50B from the y-direction and opposite sides in the x-direction. The connection member 90 may surround the second semiconductor element 50B from the y-direction and one side in the x-direction.

In the modified examples shown in FIGS. 15 and 17, the number of connection members 90 may be changed in any manner. In an example, one connection member 90 may be provided for two second semiconductor elements 50B. In this case, preferably, the connection member 90 overlaps the two second semiconductor elements 50B as viewed in the y-direction.

In the modified example shown in FIG. 16, the number of connection members 90 may be changed in any manner. In an example, among the connection members 90 shown in FIG. 16, the connection members 90 that are located at opposite ends in the x-direction may be omitted. In another example, the connection members 90 may be disposed between the two second semiconductor elements 50B located toward the insulation side surface 13B in the x-direction and between the two second semiconductor elements 50B located toward the insulation side surface 14B in the x-direction.

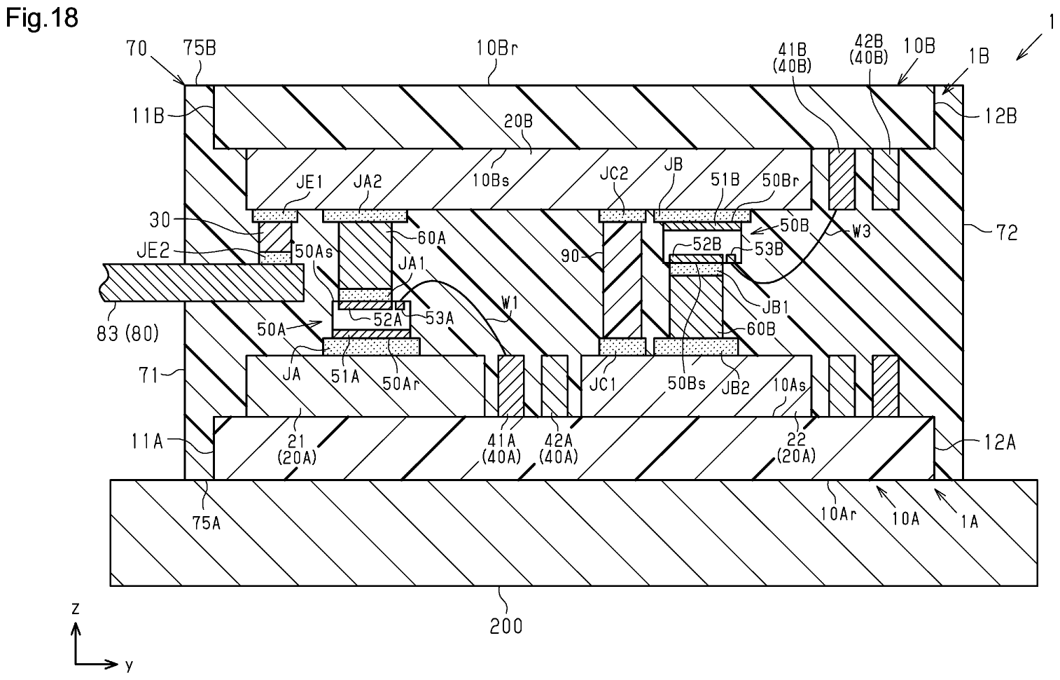

In the embodiment, the connection member 90 is connected to the first drive conductive layer 20A and the second drive conductive layer 20B by the adhesive. Instead, for example, as shown in FIG. 18, the connection member 90 may be bonded to the first drive conductive layer 20A by a first conductive bonding material JC1 such as solder or Ag paste, and the connection member 90 may be bonded to the second drive conductive layer 20B by a second conductive bonding material JC2 such as solder or Ag paste. The conductive bonding materials JC1 and JC2 have a higher thermal conductivity than the adhesive.

This structure facilitates transfer of the heat of the second semiconductor elements 50B from the second drive conductive layer 20B to the connection member 90 and from the connection member 90 to the first drive conductive layer 20A as compared to a structure in which the connection member 90 is connected to the first drive conductive layer 20A and the second drive conductive layer 20B by the adhesive.

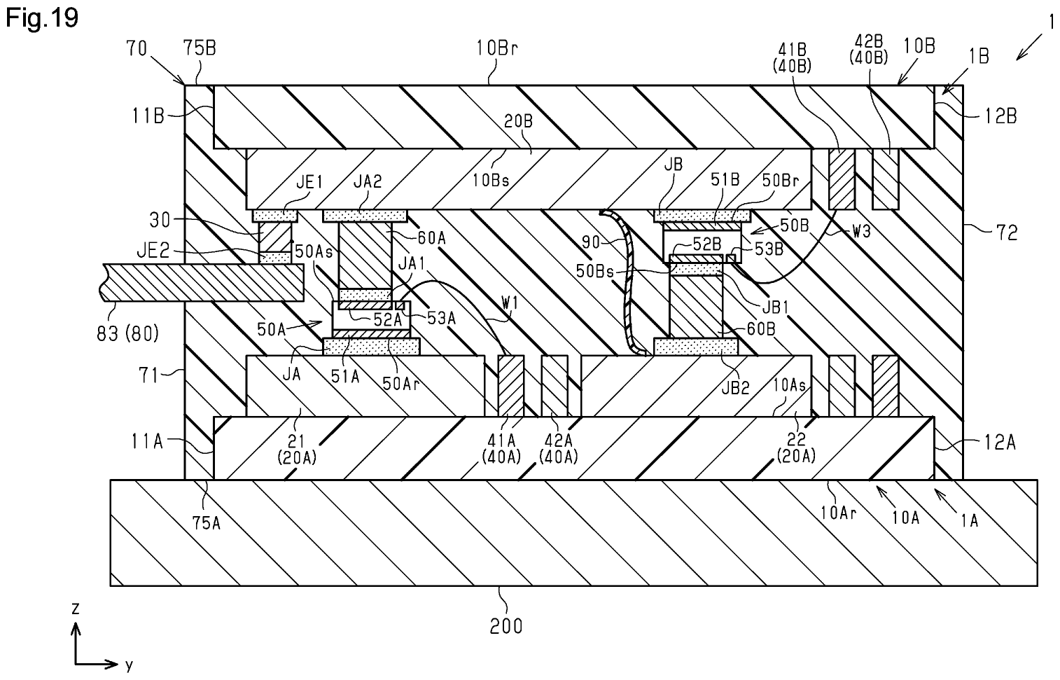

In the embodiment, the connection member 90 is formed of a flat block having a thickness-wise direction conforming to the y-direction. Instead, for example, as shown in FIG. 19, the connection member 90 may be formed of a thin plate that is S-shaped as viewed in the x-direction. In an example, the connection member 90 is formed of an electrically insulative spring. In another example, the connection member 90 may be formed of a conductive spring so that at least opposite ends of the connection member 90 in the z-direction are covered by an insulation coating. In the illustrated example, the connection member 90 is compressed by the first drive conductive layer 20A and the second drive conductive layer 20B and is in contact with the first drive conductive layer 20A and the second drive conductive layer 20B. That is, one of the opposite ends of the connection member 90 in the z-direction located closer to the first drive conductive layer 20A is urged toward the first drive conductive layer 20A. One of the opposite ends of the connection member 90 in the z-direction located closer to the second drive conductive layer 20B is urged toward the second drive conductive layer 20B.

This structure ensures that the connection member 90 is in contact with the first drive conductive layer 20A and the second drive conductive layer 20B, thereby facilitating transfer of the heat of the second semiconductor elements 50B from the second drive conductive layer 20B to the connection member 90 and from the connection member 90 to the first drive conductive layer 20A.

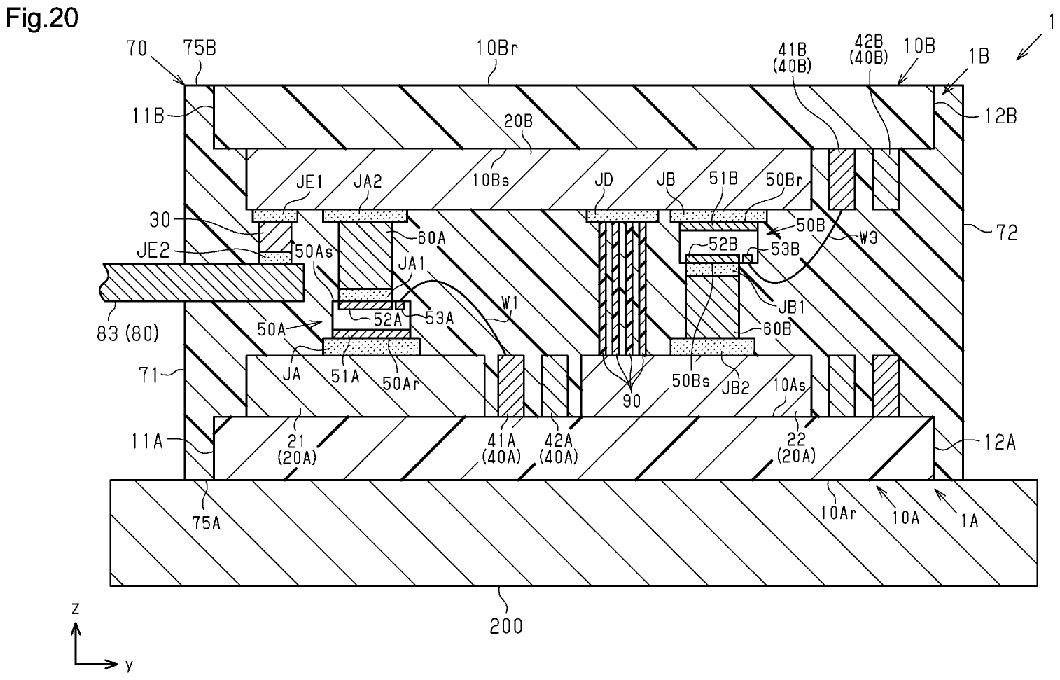

As shown in FIG. 20, the connection member 90 may be formed of spring probes. In the illustrated example, the connection member 90 is configured to be urged toward the first drive conductive layer 20A. The connection member 90 is bonded to the second drive conductive layer 20B by a conductive bonding material JD such as solder or Ag paste. This structure ensures that the connection member 90 is in contact with the first drive conductive layer 20A, thereby facilitating transfer of the heat of the second semiconductor elements 50B from the connection member 90 to the first drive conductive layer 20A.

In the embodiment, the connection member 90 is formed from an electrically insulative material. Instead, for example, the connection member 90 may be formed from a metal material such as Cu or Al. In this case, for example, the connection member 90 is connected to the first drive conductive layer 20A by an adhesive formed from an electrically insulative material, and the connection member 90 is connected to the second drive conductive layer 20B by an adhesive formed from an electrically insulative material. Thus, the connection member 90 is insulated from the first drive conductive layer 20A, and the connection member 90 is insulated from the second drive conductive layer 20B.

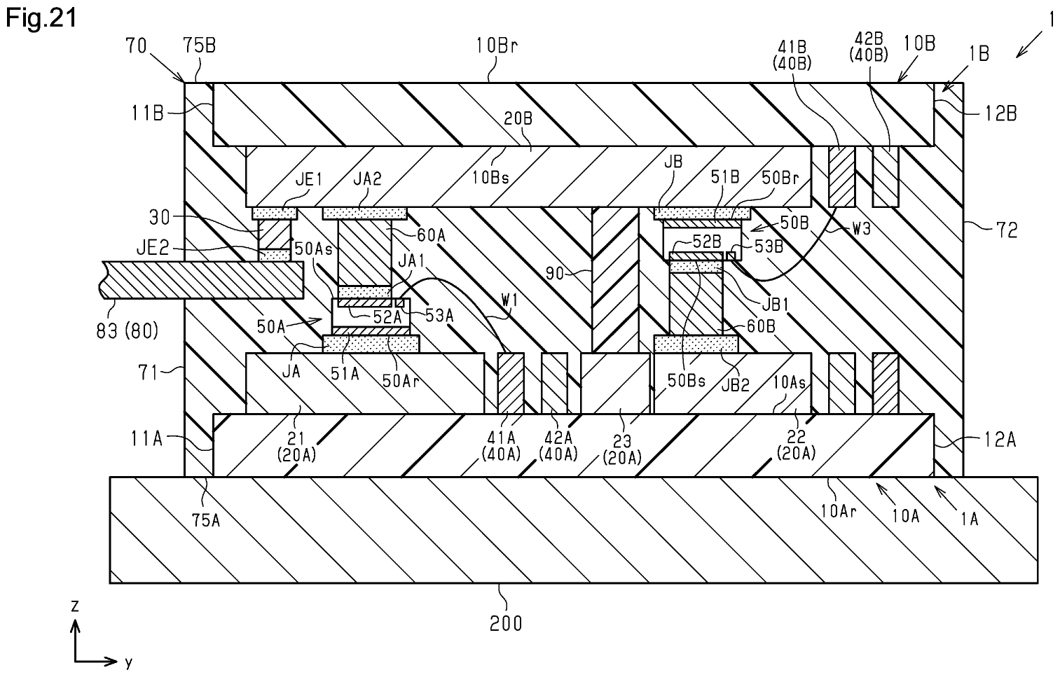

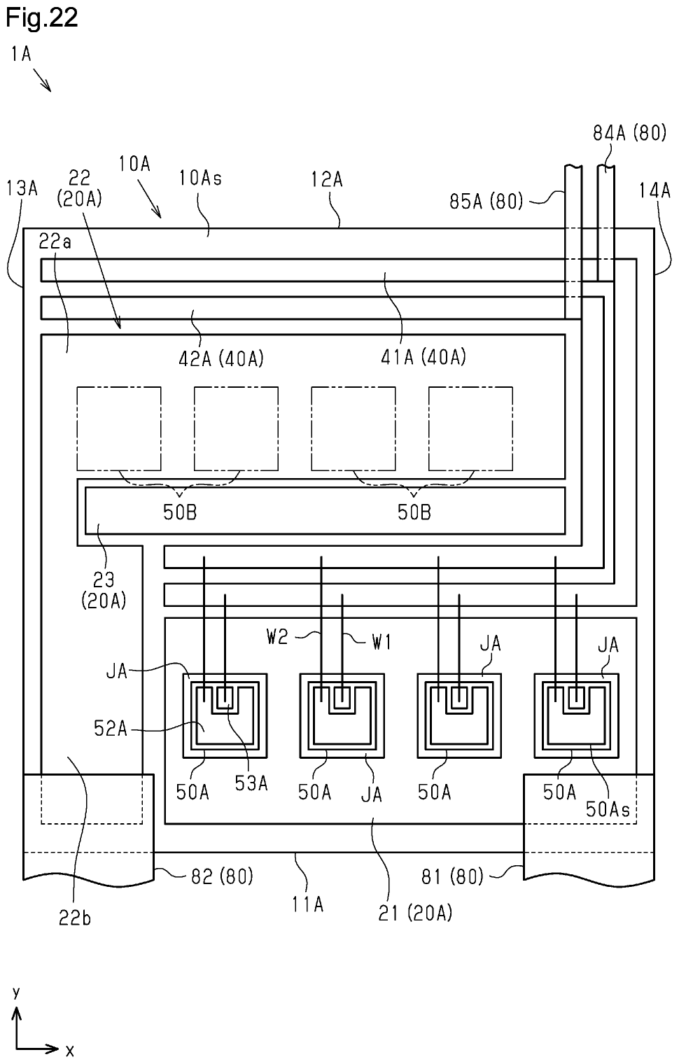

In the embodiment, the connection member 90 may be connected to a drive wire differing from the second drive wire 22. In an example, as shown in FIG. 21, the first drive conductive layer 20A may include a third drive wire 23 as a drive wire differing from the second drive wire 22. The third drive wire 23 is electrically insulated from the second drive wire 22 and disposed adjacent to the second drive wire 22 in the y-direction with a gap located therebetween. As shown in FIG. 22, the third drive wire 23 extends in the x-direction. The third drive wire 23 is spaced apart from the main wire portion 22a of the second drive wire 22 in the y-direction and spaced apart from the connection wire portion 22b in the x-direction. In this case, the connection member 90 may be formed from a conductive material, which is, for example, a metal material.

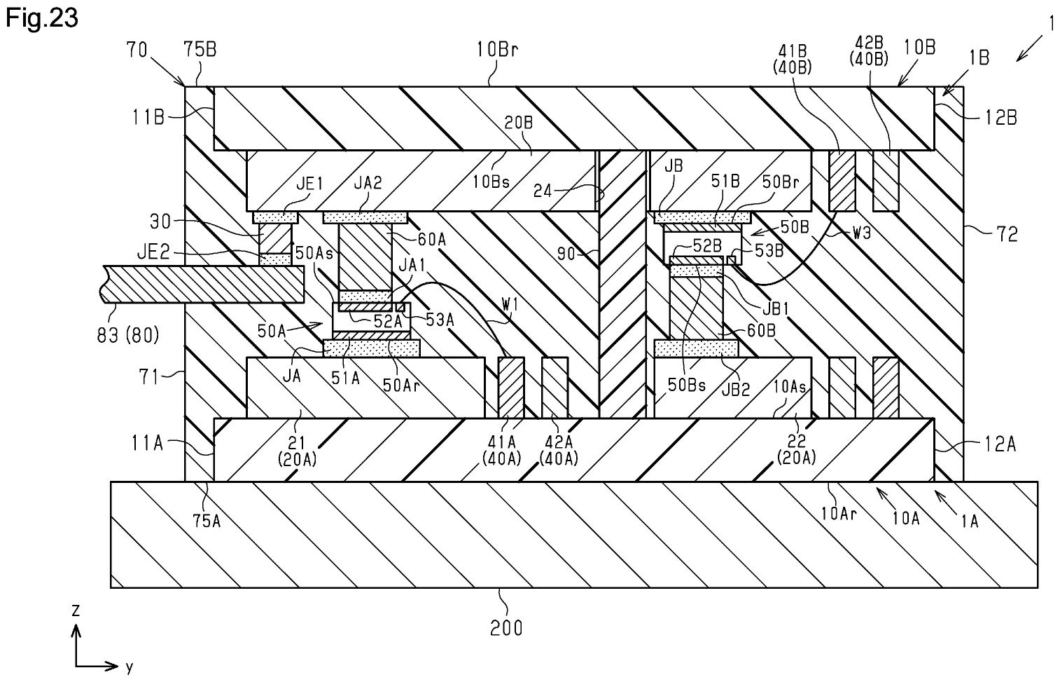

In the embodiment, the connection member 90 is connected to the first drive conductive layer 20A and the second drive conductive layer 20B. However, there is no limitation to such a structure. The connection member 90 may be connected to the first insulation main surface 10As of the first insulation member 10A instead of being connected to the first drive conductive layer 20A and may be connected to the second insulation main surface 10Bs of the second insulation member 10B instead of being connected to the second drive conductive layer 20B. In an example, as shown in FIG. 23, the connection member 90 is connected to the first insulation main surface 10As of the first insulation member 10A and the second insulation main surface 10Bs of the second insulation member 10B.

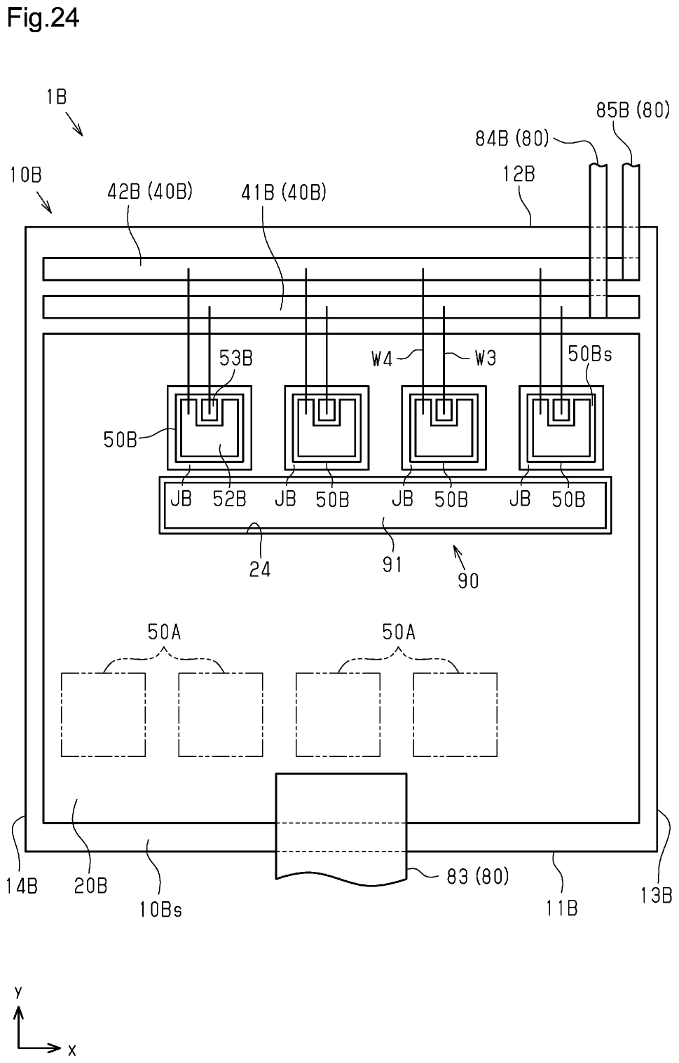

As shown in FIG. 24, a through hole 24 extends through the second drive conductive layer 20B where the connection member 90 is disposed. The through hole 24 extends through the second drive conductive layer 20B in the z-direction. The connection member 90 is inserted through the through hole 24 and is connected to the second insulation main surface 10Bs of the second insulation member 10B.

The connection member 90 may be connected over the first drive conductive layer 20A and the first insulation main surface 10As of the first insulation member 10A and may be connected over the second drive conductive layer 20B and the second insulation main surface 10Bs of the second insulation member 10B.

Thus, the connection member 90 may be connected to at least one of the first drive conductive layer 20A and the first insulation main surface 10As of the first insulation member 10A and at least one of the second drive conductive layer 20B and the second insulation main surface 10Bs of the second insulation member 10B. When the connection member 90 is connected to the first insulation main surface 10As of the first insulation member 10A or the second insulation main surface 10Bs of the second insulation member 10B, for example, the connection member 90 may be formed from a conductive material, which is, for example, a metal material.

In the embodiment, the configurations of the first connection layer 60A and the second connection layer 60B may be changed in any manner. In an example, the connection layers 60A and 60B may be formed from a conductive bonding material such as solder or Ag paste. In this case, a first connection layer connecting the first semiconductor elements 50A to the second drive conductive layer 20B includes the conductive bonding materials JA1 and JA2 formed on opposite ends of the first connection layer 60A in the z-direction. Also, a second connection layer connecting the second semiconductor elements 50B to the first drive conductive layer 20A (second drive wire 22) includes the conductive bonding materials JB1 and JB2 formed on opposite ends of the second connection layer 60B in the z-direction.

In the embodiment, the first control terminal 84A and the first detection terminal 85A may project from the resin side surface 74 in the x-direction. The second control terminal 84B and the second detection terminal 85B may project from the resin side surface 73 in the x-direction.

In the embodiment, the layout positions of the control wire 41A and the detection wire 42A may be changed in any manner. In an example, the detection wire 42A may be disposed closer to the main wire portion 22a of the second drive wire 22 than the control wire 41A.

In the embodiment, the shapes of the control wire 41A and the detection wire 42A as viewed in the z-direction may be changed in any manner. In an example, at least one of the control wire 41A and the detection wire 42A may be partially omitted from the location between the second drive wire 22 and the insulation side surface 12A in the y-direction.

In the embodiment, the layout positions of the control wire 41B and the detection wire 42B may be changed in any manner. In an example, the detection wire 42B may be located closer to the second drive conductive layer 20B than the control wire 41B.

In the embodiment, the structure of the second drive conductive layer 20B may be changed in any manner. In an example, the second drive conductive layer 20B may be divided into a first conductive portion connected to the first semiconductor elements 50A and a second conductive portion connected to the second semiconductor elements 50B. In this case, the first conductive portion and the second conductive portion may be connected by a conductive joint member.

In the embodiment, the number of first semiconductor elements 50A and second semiconductor elements 50B may be changed in any manner. The number of first semiconductor elements 50A and the number of second semiconductor elements 50B may be one to three or five or more in accordance with characteristics of the semiconductor device 1.

In the embodiment, the first connection layer 60A and the second connection layer 60B may be omitted. In this case, the first semiconductor elements 50A are directly connected to the second drive conductive layer 20B. The second semiconductor elements 50B are directly connected to the second drive wire 22 of the first drive conductive layer 20A. Alternatively, the first semiconductor elements 50A may be connected to the second drive conductive layer 20B by a conductive bonding material such as solder or Ag paste or may be in contact with the second drive conductive layer 20B and connected to the second drive conductive layer 20B. The second semiconductor elements 50B may be connected to the second drive wire 22 of the first drive conductive layer 20A by a conductive bonding material such as solder or Ag paste or may be connected to the second drive wire 22 in contact with the second drive wire 22.

In the embodiment, the bonding material JA applied between the first drive wire 21 of the first drive conductive layer 20A and the first semiconductor elements 50A may be omitted. In this case, the first semiconductor elements 50A are connected to the first drive wire 21 in contact with the first drive wire 21.

In the embodiment, the bonding material JB applied between the second drive conductive layer 20B and the second semiconductor elements 50B may be omitted. In this case, the second semiconductor elements 50B are in contact with the second drive conductive layer 20B and connected to the second drive conductive layer 20B.

In the embodiment, the first semiconductor elements 50A are disposed closer to the first insulation member 10A than the second semiconductor elements 50B, and the second semiconductor elements 50B are disposed closer to the second insulation member 10B than the first semiconductor elements 50A. Instead, for example, the first semiconductor elements 50A and the second semiconductor elements 50B may be disposed at the midpoint between the first insulation member 10A and the second insulation member 10B in the z-direction. The configuration in which the first semiconductor elements 50A and the second semiconductor elements 50B are disposed he midpoint between the first insulation member 10A and the second insulation member 10B in the z-direction includes, for example, a configuration obtained by omitting the bonding materials JA and JB and the connection layers 60A and 60B and a configuration obtained by increasing the thickness of the first drive wire 21 and the thickness of the second drive conductive layer 20B.

In the embodiment, the configurations of the first semiconductor elements 50A and the second semiconductor elements 50B may be changed in any manner. In an example, the drain electrode 51A, the source electrode 52A, and the gate electrode 53A may be formed on the first element main surface 50As of each first semiconductor element 50A. In this case, the drain electrode 51A is connected to the first drive wire 21 of the first drive conductive layer 20A by a wire or a band-shaped connection member. The drain electrode 51B, the source electrode 52B, and the gate electrode 53B may be formed on the second element main surface 50Bs of each second semiconductor element 50B. In this case, the drain electrode 51B is connected to the second drive conductive layer 20B by a wire or a band-shaped connection member.

In the embodiment, the semiconductor elements 50A and 50B may be a semiconductor element other than a switching element such as a diode.

### DESCRIPTION OF THE REFERENCE NUMERALS

1) semiconductor device; 10A) first insulation member; 10As) first insulation main surface; 10Ar) first insulation rear surface; 10B) second insulation member; 10Bs) second insulation main surface; 10Br) second insulation rear surface; 20A) first drive conductive layer; 21) first drive wire; 22) second drive wire; 23) third drive wire; 20B) second drive conductive layer; 40B) control conductive layer; 60A) first connection layer; 60B) second connection layer; 50A) first semiconductor element; 50As) first element main surface; 50Ar) first element rear surface; 51A) drain electrode (first rear surface drive electrode); 52A) source electrode (first main surface drive electrode); 50B) second semiconductor element; 50Bs) second element main surface; 50Br) second element rear surface; 51B) drain electrode (second rear surface drive electrode); 52B) source electrode (second main surface drive electrode); 70) encapsulation resin; 90) connection member; 92) end opposing wall (portion bordering, in a second direction, one of the second semiconductor elements located at opposite ends in the second direction); 93) intermediate opposing wall (portion disposed between ones of second semiconductor elements located adjacent to each other in the second direction); 200) cooler

1. A semiconductor device, comprising:
a first insulation member including a first insulation main surface and a first insulation rear surface that face opposite sides in a thickness-wise direction, the first insulation rear surface being exposed;
a first drive conductive layer disposed on the first insulation main surface;
a first semiconductor element mounted on the first drive conductive layer;
a second insulation member including a second insulation main surface and a second insulation rear surface that face opposite side in the thickness-wise direction, the second insulation rear surface being exposed, the second insulation member being spaced apart from the first insulation member so that the second insulation main surface is opposed to the first insulation main surface in the thickness-wise direction;
a second drive conductive layer disposed on the second insulation main surface;
a second semiconductor element mounted on the second drive conductive layer;
a connection member forming a heat conduction path between at least one of the first insulation member and the first drive conductive layer and at least one of the second insulation member and the second drive conductive layer; and
an encapsulation resin encapsulating the first semiconductor element, the second semiconductor element, and the connection member,
wherein the connection member has a higher thermal conductivity than the encapsulation resin.

2. The semiconductor device according to claim 1, wherein the connection member is connected to the second drive conductive layer.

3. The semiconductor device according to claim 1 or 2, wherein as viewed in the thickness-wise direction, the connection member is disposed closer to the second semiconductor element than to the first semiconductor element.

4. The semiconductor device according to claim 1, wherein
the first semiconductor element includes a first element main surface and a first element rear surface that face opposite sides in the thickness-wise direction,
the first semiconductor element is disposed so that the first element rear surface is opposed to the first drive conductive layer in the thickness-wise direction,
the first element rear surface includes a first rear surface drive electrode,
the first element main surface includes a first main surface drive electrode,
the second semiconductor element includes a second element main surface and a second element rear surface that face opposite sides in the thickness-wise direction,
the second semiconductor element is disposed so that the second element rear surface is opposed to the second drive conductive layer in the thickness-wise direction,
the second element rear surface includes a second rear surface drive electrode, and
the second element main surface includes a second main surface drive electrode.

5. The semiconductor device according to claim 4, wherein
the first drive conductive layer includes a first drive wire and a second drive wire, and
the first semiconductor element is mounted on the first drive wire so that the first rear surface drive electrode is electrically connected to the first drive wire.

6. The semiconductor device according to claim 5, wherein
the second semiconductor element is mounted on the second drive conductive layer so that the second rear surface drive electrode is electrically connected to the second drive conductive layer,
the second semiconductor element is spaced apart from and opposed to the second drive wire in the thickness-wise direction, and
a second connection layer is disposed between the second semiconductor element and the second drive wire to electrically connect the second main surface drive electrode and the second drive wire.

7. The semiconductor device according to claim 6, wherein
the first semiconductor element is spaced apart from and opposed to the second drive conductive layer in the thickness-wise direction, and
a first connection layer is disposed between the first semiconductor element and the second drive conductive layer to electrically connect the first main surface drive electrode and the second drive conductive layer.

8. The semiconductor device according to claim 5, wherein
when two directions that are orthogonal to the thickness-wise direction and orthogonal to each other are referred to as a first direction and a second direction, the first drive conductive layer includes a third drive wire disposed adjacent to the second drive wire in the first direction,
the third drive wire is electrically insulated from the second drive wire, and
the connection member connects the third drive wire and the second drive conductive layer.

9. The semiconductor device according to claim 5, wherein the connection member is formed from an electrically insulative material and connects the first drive wire and the second drive conductive layer.

10. The semiconductor device according to claim 5, wherein
the first semiconductor element is one of first semiconductor elements,
the second semiconductor element is one of second semiconductor elements,
when two directions that are orthogonal to the thickness-wise direction and orthogonal to each other are referred to as a first direction and a second direction, the first semiconductor elements are arranged at a same position in the first direction and spaced apart from each other in the second direction,
the second semiconductor elements are arranged at a same position in the first direction and space apart from each other in the second direction,
the first semiconductor elements are spaced apart from the second semiconductor elements in the first direction, and
as viewed in the thickness-wise direction, the connection member extends in the second direction.

11. The semiconductor device according to claim 10, wherein the connection member overlaps all of the second semiconductor elements as viewed in the first direction.

12. The semiconductor device according to claim 11, wherein the connection member is disposed adjacent to all of the second semiconductor elements in the first direction.

13. The semiconductor device according to claim 10, wherein the connection member is smaller in dimension in the first direction than the second semiconductor element.

14. The semiconductor device according to claim 10, wherein the connection member includes a portion bordering, in the second direction, one of the second semiconductor elements located at opposite ends in the second direction.

15. The semiconductor device according to claim 10, wherein the connection member includes a portion disposed between ones of the second semiconductor elements located adjacent to each other in the second direction.

16. The semiconductor device according to claim 1, wherein the connection member includes a spring.

17. The semiconductor device according to claim 1, wherein the connection member includes one or more rod-shaped spring probes.

18. The semiconductor device according to claim 1, further comprising: a control conductive layer disposed on the second insulation main surface, wherein as viewed in the thickness-wise direction, the connection member and the control conductive layer are located at opposite sides of the second semiconductor element.

19. The semiconductor device according to claim 1, wherein each of the first insulation member and the second insulation member is formed from a ceramic.
